(19) United States
(12) Patent Application Publication
(10) Pub. No.: US 2007/0128738 A1
(43) Pub. Date: Jun. 7, 2007

(54) Pattern formed body and method for manufacturing same

(76) Inventors: Hironori Kobayashi, Tokyo (JP); Ayao Matsukawa, Tokyo (JP)

Correspondence Address: SEYFARTH SHAW LLP, 131 S. DEARBORN ST., SUITE2400, CHICAGO, IL, 60603-5803, US

(21) Appl. No.: 11/472,890

(22) Filed: Jun. 22, 2006

(30) Foreign Application Priority Data
Jun. 23, 2005 (JP) 2005-183750

(51) Int. Cl. H01L 21/00

(52) U.S. Cl. 438/8

(57) ABSTRACT

A main object of the present invention is to provide a high quality pattern formed body, wherein only the target region is made liquid repellent with a high precision at the time of forming a pattern made of a lyophilic region and a liquid repellent region by use of plasma radiating; and a method for manufacturing the same. To achieve the object, the present invention provides a method for manufacturing a pattern formed body comprising a plasma radiating step of radiating plasma to a patterning substrate having: a base material; a photocatalyst containing layer formed on the base material and containing at least a photocatalyst; and a resin layer formed in a pattern form on the photocatalyst containing layer and containing at least a resin, wherein a fluorine compound is used as an introduction gas to radiate the plasma to make the upper face of the resin layer liquid repellent.

### BACKGROUND OF THE INVENTION

1. Field of the Invention

The present invention relates to a pattern formed body wherein a region having liquid repellency and a region having lyophilicity are formed with a high precision, and a method for manufacturing the same.

2. Description of the Related Art

Conventionally, various methods have been suggested as a method for manufacturing a pattern formed body wherein various patterns such as designs, images, characters, and circuits are formed on a base material.

As a method to form a pattern highly precisely, the following is known: a method for manufacturing a pattern formed body by photolithography of radiating light in a pattern form to a photoresist layer applied on a base material and developing the photoresist after the radiation to perform etching, or of using a material having functionality as a photoresist and radiating light to the photoresist so as to form a target pattern directly.

The formation of a highly precise pattern by photolithography is used for the formation of a colored pattern of a color filter used in such as a liquid crystal display, the formation of a microlens, the manufacture of a precise electric circuit board, the manufacture of a chromium mask used for pattern exposure, and so forth. In accordance with methods therefor, it is necessary to use a photoresist and further develop the photoresist with a liquid developer after the resist is exposed to light and then perform etching. Accordingly, there are caused such problems that waste liquid generated needs to be disposed. Additionally, there also arises a problem that when a functional material is used as the photoresist, the material is deteriorated by the alkaline solution or the like that is used for the development.

A high precise pattern of a color filter or the like is frequently formed by printing. However, the pattern formed by printing has problems about location accuracy and others. Thus, a highly precise pattern is not easily formed.

Thus, suggested is a method of forming a bank for storing a colored layer forming coating solution, for colored layer formation on the base material, treating this bank with plasma using a fluorine compound as an introduction gas to make the bank liquid repellent, and then forming a functional part, which is made of a colored layer or the like, by such as an ink jet method (Japanese Patent Application Laid-Open No. 2000-187111). According to this method, fluorine can be introduced only into the bank made of an organic material by the plasma treatment, and no fluorine is introduced onto the base material made of an inorganic material. This makes it possible that a functional part forming coating solution for functional part formation is coated only into an opening part where the bank is not formed, thereby forming the functional part.

According to this method, however, when impurities, such as residues generated when the bank is formed adhere to the opening part, fluorine is unfavorably introduced onto the impurities by the plasma treatment. This matter hinders the functional part forming coating solution from wetting and spreading onto the opening part when this coating solution is coated. Thus, at the time of forming, for example, of a colored layer as the functional part, defects such as white spots may be generated in the colored layer.

### SUMMARY OF THE INVENTION

Thus, it is desired to provide: a high quality pattern formed body, wherein only the target region is made liquid repellent with a high precision at the time of forming a pattern made of a lyophilic region and a liquid repellent region by use of plasma radiation, and a method for manufacturing the same.

The invention provides a method for manufacturing a pattern formed body comprising a plasma radiating step of radiating plasma to a patterning substrate having: a base material; a photocatalyst containing layer formed on the base material and containing at least a photocatalyst; and a resin layer formed in a pattern form on the photocatalyst containing layer and containing at least a resin, wherein a fluorine compound is used as an introduction gas to radiate the plasma to make the upper face of the resin layer liquid repellent.

According to the invention, fluorine can be introduced into the resin layer through the plasma radiating step, so that the surface of the resin layer can be made liquid repellent. Moreover, according to the invention, the photocatalyst in the photocatalyst containing layer can be excited by light generated when the plasma is radiated, so that liquid repellent materials, such as residues when the resin layer is formed, which are present in an opening part partitioned by the resin layer can be removed. Accordingly, the resin layer can be made liquid repellent; thus, a wettability difference between the resin layer and the opening part is used to manufacture a pattern formed body capable of forming a highly precise functional part.

In the invention, an intermediate layer containing a silane coupling agent or a polymer of the silane coupling agent may be formed on the photocatalyst containing layer, and the resin layer may be formed in the pattern form on the intermediate layer. In this case, in a region where the intermediate layer is exposed, a Si—C bond of the silane coupling agent or the polymer thereof is broken by the plasma radiation, whereby an organic group bonded to the Si element is removed and an OH group or the like is introduced thereto. Consequently, a wettability difference between the surface of the resin layer and the region where the intermediate layer is exposed can be made large. The use of this wettability difference makes it possible to manufacture a pattern formed body capable of forming a functional part highly precisely only in the region) where the intermediate layer is exposed. Furthermore, in this case, given is an advantage that the intermediate layer makes good adhesive property between the resin layer or the functional part formed on this pattern formed body and the photocatalyst containing layer.

The invention preferably has liquid repellent material removing step of radiating energy to the opening part partitioned by the resin layer, thereby removing liquid repellent materials on the surface of the opening part. This makes it possible to remove liquid repellent materials, such as residues which are generated when the resin layer is formed and are present in the opening part partitioned by the resin layer, and fluorine introduced in the residues through the plasma radiating step, by the action of the photocatalyst accompanying energy radiation. Accordingly, the wettability difference between the lyophilic region and the liquid repellent region can be made larger. The use of such wettability difference makes it possible to manufacture a pattern formed body capable of forming a functional part with a higher precision only in the lyophilic region.

In the invention, the resin layer may be a light shielding part containing at least a light shielding material. This makes the following possible: for example, when a colored layer is formed on the lyophilic region of the pattern formed body manufactured by the invention to produce a color filter, the resin layer is used as a black matrix; thus, the color filter is effectively produced.

The invention provides a pattern formed body having: a base material; a photocatalyst containing layer formed on the base material and containing at least a photocatalyst; and a liquid repellent resin layer formed in a pattern form on the photocatalyst containing layer and containing, in its surface, a fluorine atom, wherein a region of the photocatalyst containing layer where the liquid repellent resin layer is not formed is rendered a lyophilic region which contain, in its surface, no fluorine atom.

According to the invention, fluorine is contained in the surface of the liquid repellent resin layer, and further fluorine is not contained in the region where the photocatalyst is exposed. For this reason, the wettability difference between the surface of the liquid repellent resin layer and the region where the photocatalyst is exposed, that is, the lyophilic region is large. The use of the wettability difference between these surfaces makes it possible to manufacture a pattern formed body capable of forming a functional part highly precisely only in the region where the photocatalyst containing layer is exposed. Moreover, in the invention, a functional part, which is made of a colored layer or the like, is formed in an opening part in the pattern formed body to manufacture a functional element such as a color filter. In this case, the fluorine atom is not contained in the surface of the photocatalyst containing layer, so as to produce an advantage of making it possible to prevent any fluorine atom in the surface of the photocatalyst containing layer from eluting out in subsequent steps so as to give a bad effect onto the functional part.

The invention also provides a pattern formed body having: a base material; a photocatalyst containing layer formed on the base material and containing at least a photocatalyst; an intermediate layer formed on the photocatalyst containing layer and containing a silane coupling agent or a polymer of the silane coupling agent; and a liquid repellent resin layer formed in a pattern form on the intermediate layer and containing, in its surface, a fluorine atom, wherein a region of the intermediate layer where the liquid repellent resin layer is not formed is a lyophilic region.

According to the invention, fluorine is contained in the surface of the liquid repellent resin layer; therefore, the wettability difference between the surface of the liquid repellent resin layer and the region where the intermediate layer is exposed is used to make it possible to manufacture a pattern formed body capable of forming a functional part highly precisely only in the region where the intermediate layer is exposed.

In the invention, the region of the intermediate layer where the liquid repellent resin layer is not formed is preferably rendered a lyophilic region having a contact angle with water in its surface of 60° or less. This makes it possible to make large the wettability difference between the surface of the resin layer and the region where the intermediate layer is exposed so as to form the functional part into a more highly precise pattern.

In the invention, the liquid repellent resin layer may be a liquid repellent light shielding part containing at least a light shielding material. This makes the following possible: for example, when a colored layer is formed on the lyophilic region of the pattern formed body of the invention to produce a color filter, the resin layer is used as a black matrix.

The invention also provides: a color filter, wherein a colored layer is formed on the lyophilic region of the above-mentioned pattern formed body; an organic electroluminescent (hereinafter, may referred to as organic EL) element, wherein an organic EL layer is formed on the lyophilic region of the above-mentioned pattern formed body; and a microlens, wherein a lens is formed on the lyophilic region of the above-mentioned pattern formed body. In the pattern formed body, the region where the liquid repellent resin layer is formed, that is, the liquid repellent region, and the lyophilic region are formed; therefore, the use of a wettability difference therebetween makes it possible to manufacture a functional element where various functional parts can be formed only in the lyophilic region with a high precision.

Furthermore, the invention also provides a cell culturing substrate, wherein the upper face of the lyophilic region of the above-mentioned pattern formed body is used to culture a cell. According to the invention, in the pattern formed body, the liquid repellent region and the lyophilic region are formed; therefore, the use of a wettability difference therebetween makes it possible to manufacture a cell culturing substrate wherein cells are cultured into a highly precise pattern form only in the lyophilic region.

The invention provides a method for manufacturing a pattern formed body comprising:

a plasma radiating step of radiating plasma to a patterning substrate having; a base material, a photocatalyst containing layer formed on the base material and containing at least a photocatalyst, and a light shielding part formed on the photocatalyst containing layer and containing at least a light shielding material and a resin, wherein a fluorine compound is used as an introduction gas to radiate the plasma to make the upper face of the light shielding part liquid repellent; and

a liquid repellent material removing step of radiating energy to an opening part partitioned by the light shielding part to remove liquid repellent materials on the surface of the opening part.

According to the invention, fluorine can be introduced into an organic material through the plasma radiating step; accordingly, the upper face of the light shielding part can be rendered a liquid repellent region. When the liquid repellent material removing step is performed after the plasma radiating step, it is possible to remove liquid repellent materials, such as residues which are generated when the light shielding part is formed and are present in the opening part partitioned by the light shielding part, and fluorine introduced into the residues through the plasma radiating step, by the action of the photocatalyst accompanying energy radiation. This makes it possible to render only the light shielding part a liquid repellent region so as to manufacture a pattern formed body capable of forming a highly precise functional part.

In the invention, the liquid repellent material removing step may be rendered a step of arranging the opening part and a photocatalyst processing layer side substrate containing a base body and a photocatalyst processing layer formed on the base body and containing at least a photocatalyst so as to have a gap between the photocatalyst processing layer and the opening part, and then radiating energy to the opening part partitioned by the light shielding part. This makes it possible that in the liquid repellent material removing step, the liquid repellent materials present in the opening part partitioned by the light shielding part can be removed by the action of the photocatalyst contained in the photocatalyst processing layer as well as the photocatalyst contained in the photocatalyst containing layer. Accordingly, the liquid repellent material removing step can be more effectively performed.

In the invention, the liquid repellent material removing step may be a step of radiating the energy from the side of the base material. In this case, the light shielding part is formed; thus, even if the energy is radiated to the entire surface from the side of the base material, the energy can be radiated only to the opening part partitioned by the light shielding part.

In the invention, the liquid repellent material removing step may be a step of radiating the energy from the side of the light shielding part. Even if, in this case, the base material and the photocatalyst containing layer do not transmit the energy, the liquid repellent materials in the opening part can be removed.

The invention also provides a pattern formed body having a base material, a photocatalyst containing layer formed on the base material and containing at least a photocatalyst, and a light shielding part formed on the photocatalyst containing layer and containing at least a light shielding material and a resin, wherein the photocatalyst containing layer does not contain any fluorine atom.

The invention has an advantage that when a functional part, such as a color layer, is formed in the opening part in the pattern formed body to manufacture a functional element such as a color filter, it is possible to prevent the fluorine atom in the photocatalyst containing layer from eluting out in subsequent steps so as to produce a bad effect onto the functional part since no fluorine atom is contained in the photocatalyst containing layer.

In the invention, the film thickness of the photocatalyst containing layer ranges preferably from 10 to 200 nm. This makes it possible to make the optical transparency of the pattern formed body itself good and further makes the haze value thereof low. Thus, for example, when the pattern formed body of the invention is used to manufacture a display device such as a color filter, advantages are produced.

According to the invention, the resin layer can be made liquid repellent. Thus, a difference in contact angle with the liquid between the resin layer and the opening part is used to make it possible to manufacture a pattern formed body capable of forming a highly precise functional part.

### BRIEF DESCRIPTION OF THE DRAWINGS

FIG. 1 is a process drawing illustrating an example of a method for manufacturing the pattern formed body of the invention;

FIG. 2 is an explanatory view for explaining the liquid repellent material removing step in the method for manufacturing the pattern formed body of the invention;

FIG. 3 is another explanatory view for explaining the liquid repellent material removing step in the method for manufacturing the pattern formed body of the invention;

FIG. 4 is still another explanatory view for explaining the liquid repellent material removing step in the method for manufacturing the pattern formed body of the invention;

FIG. 5 is yet another explanatory view for explaining the liquid repellent material removing step in the method for manufacturing the pattern formed body of the invention;

FIG. 6 is a schematic sectional view illustrating an example of a patterning substrate used in the method for manufacturing the pattern formed body of the invention;

FIGS. 7A and 7B are each a process drawing illustrating an example of the method for manufacturing the pattern formed body of the invention.

FIG. 8 is still another explanatory view for explaining the liquid repellent material removing step in the method for manufacturing the pattern formed body of the invention;

FIG. 9 is still another explanatory view for explaining the liquid repellent material removing step in the method for manufacturing the pattern formed body of the invention;

FIG. 10 is still another explanatory view for explaining the liquid repellent material removing step in the method for manufacturing the pattern formed body of the invention;

FIG. 11 is a schematic sectional view illustrating an example of the pattern formed body of the invention; and

FIG. 12 is a schematic sectional view illustrating another example of the pattern formed body of the invention.

### DESCRIPTION OF THE PREFERRED EMBODIMENT

The present invention relates to a method for manufacturing a pattern formed body wherein a region having liquid repellency and a region having lyophilicity are formed with a high precision; and a pattern formed body. The following will describe each of them in detail.

A. Method for Manufacturing Pattern Formed Body

First, the method of the invention for manufacturing a pattern formed body is described. This method for manufacturing pattern formed body is classified into the following two aspects. These will be separately described hereinafter.

1. First Aspect

The first aspect of the method for manufacturing the pattern formed body of the invention is first described herein. A method for manufacturing a pattern formed body of the first aspect comprising a plasma radiating step of radiating plasma to a patterning substrate having: a base material; a photocatalyst containing layer formed on the base material and containing at least a photocatalyst; and a resin layer formed in a pattern form on the photocatalyst containing layer and containing at least a resin, wherein a fluorine compound is used as an introduction gas to radiate the plasma to make the upper face of the resin layer liquid repellent.

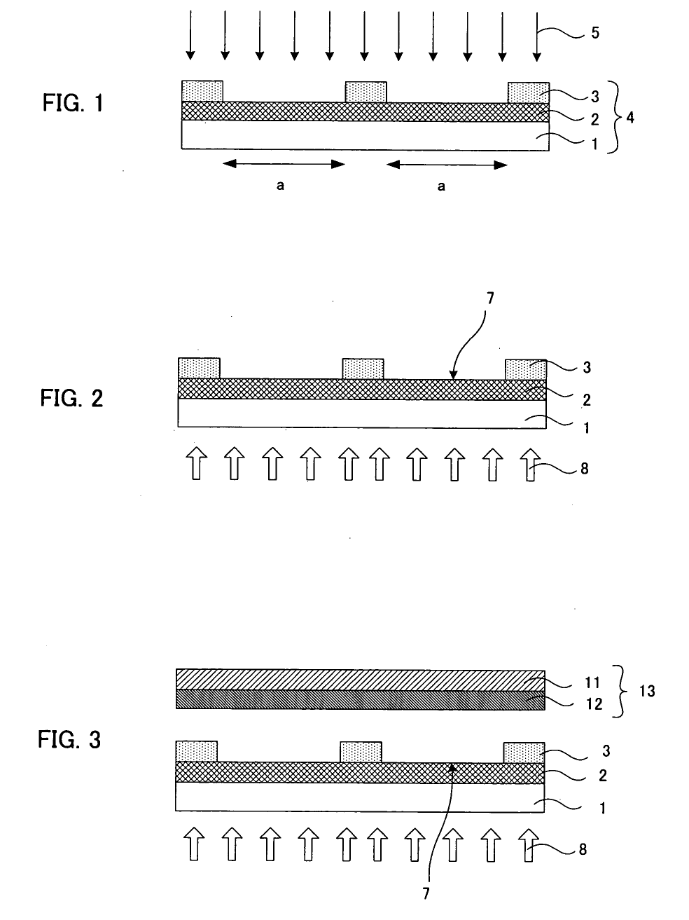

As illustrated in, for example, FIG. 1, the method for manufacturing the pattern formed body of the present aspect is a method for manufacturing a pattern formed body by performing a plasma radiating step of radiating plasma 5 to a patterning substrate 4 having a base material 1, a photocatalyst containing layer 2 formed on the base material 1, and a resin layer 3 formed in a pattern form on the photocatalyst containing layer 2. At this time, the plasma radiation is performed from the side of the resin layer 3, using a fluorine compound as an introduction gas.

When the plasma is radiated using the fluorine compound as the introduction gas, fluorine can be introduced into any organic material. Thus, the surface can be made liquid repellent. According to the aspect, therefore, the upper face of the resin layer can be rendered a liquid repellent region by performing the plasma radiation in the plasma radiating step. In general, however, in an opening part as described above, residues generated when the resin layer is formed, and so on are present, so that fluorine is introduced to the residues, and so on in a plasma radiating step as described above. Accordingly, a liquid repellent region may be formed not only in the resin layer but also on the opening part.

Since the photocatalyst containing layer is formed in the aspect, the photocatalyst of the photocatalyst containing layer exposed in the opening part (for example, a part represented by “a” in FIG. 1) can be excited by light generated by the plasma radiation. Accordingly, at the same time when fluorine is introduced to the resin layer surface by the plasma radiation, the liquid repellent material present in the opening part, such as the residues adhering to the opening part surface and fluorine introduced to the residues, can be removed. This makes it possible to use the upper of the resin layer and that of the opening part as a liquid repellent region and a lyophilic region, respectively. Thus, it is possible to use a wettability difference between the upper of the resin layer and that of the opening part to manufacture a pattern formed body on which various functional parts can be formed with a high precision. The following will describe the plasma radiating step and other steps in the method for manufacturing the pattern formed body of the aspect in detail.

A. Plasma Radiating Step

First, the plasma radiating step in the present aspect is described. This step is a step of radiating plasma to a patterning substrate having a base material, a photocatalyst containing layer formed on the base material and containing at least a photocatalyst, and a resin layer formed in a pattern form on the photocatalyst containing layer and containing at least a resin, wherein a fluorine compound is used as an introduction gas to radiate the plasma to make the upper face of the resin layer liquid repellent.

In the aspect, as the resin layer of the patterning substrate, a layer containing at least a resin is used, as will be detailed later; therefore, when plasma is radiated in the present step, fluorine can be introduced onto the resin layer so that the upper face of the resin layer can be used as a region having liquid repellency. Moreover, when plasma is radiated in the step, light generated when the plasma is radiated makes it possible to excite the photocatalyst in the photocatalyst containing layer in the opening part partitioned by the resin layer so as to remove the liquid repellent materials present in the opening part effectively. The following will describe each of the patterning substrate and the method for radiating the plasma used in the step.

(Patterning Substrate)

First, the patterning substrate used in the step is described. This patterning substrate is not particularly limited as long as the substrate has a base material, a photocatalyst containing layer formed on the base material, and a resin layer formed in a pattern form on the photocatalyst containing layer, and makes it possible to introduce fluorine onto the upper face of the resin layer by plasma radiation which will be detailed later. This patterning substrate may, for example, a substrate wherein between the base material and the photocatalyst containing layer such as an anchor layer for improving the adhesive property therebetween may be formed, or wherein between the photocatalyst containing layer and the resin layer such as a primer layer for improving the adhesive property therebetween may be formed. Each of the constituents of the patterning substrate used in the step will be described hereinafter.

(1) Resin Layer

The resin layer used in the present aspect is a layer containing a resin, and the shape, the film thickness, and other points thereof are appropriately selected in accordance with such as the usage of the pattern formed body or the kind of the resin layer.

This resin layer is appropriately selected in accordance with the usage of the pattern formed body, and may be, for example, a layer having transparency, a layer having light shielding property, or a colored layer. In the aspect, the width of the resin layer is preferably 1 μm or more, more preferably 5 μm or more. This makes it possible that even if functional parts are formed in regions adjacent to each other with the resin layer sandwiched therebetween, these functional parts are prevented from being linked to each other.

The film thickness of the resin layer is not particularly limited, either, as long as the film thickness makes it possible that fluorine is introduced into the resin layer in the present step, whereby the layer expresses liquid repellency. The film thickness, which is appropriately selected in accordance with the usage of the pattern formed body or others, is set into the range usually from about 0.01 μm to 1 mm, preferably from about 0.1 μm to 0.1 mm.

The material used to form the resin layer is not particularly limited as long as the material is capable of forming the resin layer mentioned above. For example, the following can be used: a single or mixture made of one or more selected from resins such as polyimide resin, acrylic resin, epoxy resin, polyacrylamide, polyvinyl alcohol, gelatin, casein and cellulose; a photosensitive resin; or an O/W emulsion type resin composition such as a product obtained by emulsifying a reactive silicone.

The method for forming the resin layer may be equal to an ordinary method for forming a layer made of the above-mentioned material(s) into a pattern form, and is, for example, printing or photolithography. When the photocatalyst containing layer, which will be detailed later, contains therein a material having a wettability variable by the action of the photocatalyst accompanying energy radiation, the method for forming the resin layer may be a method of radiating energy in the a pattern form for forming the resin layer so as to vary the contact angle of the photocatalyst containing layer with liquid into a pattern form, and then using this wettability difference to form the resin layer. Such a patterning method using the photocatalyst containing layer may be identical with, for example, a method disclosed in JP-A No. 2002-40230.

The resin layer used in the aspect may be a light shielding part containing a light shielding material. This case has an advantage that when the pattern formed body manufactured according to the aspect is used to produce, for example, a color filter, the resin layer can be used as a black matrix.

In the aspect, the method for forming this light shielding part may be, for example, a method of forming a layer wherein light shielding particles made of such as carbon fine particles, a metal oxide, an inorganic pigment, or an organic pigment are incorporated into a resin binder into a pattern form. Examples of the resin binder to be used may be: a single or mixture made of one or more selected from resins such as polyimide resin, acrylic resin, epoxy resin, polyacrylamide, polyvinyl alcohol, gelatin, casein and cellulose; a photosensitive resin; or an O/W emulsion type resin composition such as a product obtained by emulsifying a reactive silicone. The method for patterning this resin light shielding part may be an ordinarily-used method, such as photolithography or printing.

In the aspect, the light shielding part may be formed by thermal transfer process. The thermal transfer process for forming the light shielding part is ordinarily a process of: arranging, on a base material, a thermal transfer sheet wherein a photothermally converting layer and a light shielding part transferring layer are formed on a single face of a transparent film substrate; and radiating energy to a region where the light shielding part is to be formed, thereby transferring the light shielding part transferring layer onto the base material so as to form the light shielding part.

The light shielding part transferred by the thermal transfer process is usually composed of a light shielding material and a binder. As the light shielding material, inorganic particles made of such as carbon black or titanium black can be used. The diameter of such light shielding material particles is preferably from 0.01 to 1.0 μm, more preferably from 0.03 to 0.3 μm.

The binder is preferably rendered a resin composition having thermal plasticity and thermosetting property. The binder is preferably composed of: a resin material having a thermosetting property functional group and a softening point ranging from 50 to 150° C., in particular from 60 to 120° C.; a hardener; and so forth. A specific example of such a material is a combination of an epoxy compound or epoxy resin having, in a single molecule thereof, two or more epoxy groups with a latent hardener therefor. The latent hardener for the epoxy resin may be a hardener which does not have reactivity with an epoxy group up to a predetermined temperature but has a molecular structure variable to have reactivity with the epoxy group when the hardener is heated so that the temperature of the hardener reaches the activation temperature thereof. A specific example thereof may be a neutral salt, a complex, a block compound, a high melting point compound, or a micro-encapsulated product of an acidic or basic compound having reactivity with an epoxy resin. The light shielding part may contain, besides the above-mentioned materials, such as a releasing agent, an adhesion aid, an antioxidant, or a dispersing agent.

(2) Photocatalyst Containing Layer

Next, the photocatalyst containing layer of the patterning substrate used in the present step is described. This photocatalyst containing layer is not particularly limited as long as the layer contains at least a photocatalyst and makes it possible to remove liquid repellent materials present in the opening part partitioned by the resin layer, which are present on the surface of the photocatalyst containing layer, by photocatalyst-action resulting from light generated at the time of plasma radiation. The photocatalyst containing layer preferably makes it possible to remove the liquid repellent materials present in the opening part partitioned by the resin layer, which are present on the photocatalyst containing layer by the action of the photocatalyst which accompanies energy radiation in a liquid repellent material removing step which will be described later. This makes it possible to excite the photocatalyst in the photocatalyst containing layer by the energy radiation to remove effectively the liquid repellent materials, such as the residues adhering onto the surface of the photocatalyst containing layer and the introduced fluorine.

This photocatalyst containing layer may be, for example, a layer made only of the photocatalyst, or a layer containing the photocatalyst and a binder. When the photocatalyst containing layer contains the binder also, fluorine may be introduced thereinto by plasma radiation which will be detailed later. However, through the liquid repellent material removing step which will be detailed later, or the like, the fluorine and the like can be removed by the action of the photocatalyst accompanying energy radiation. In the aspect, by the action of the photocatalyst excited by light generated in the plasma radiation also, the fluorine and the like can be removed.

When the photocatalyst containing layer is made only of the photocatalyst, the efficiency of removing the liquid repellent materials present in the opening part on the base material is improved, so as to make the time for the processing short and give other advantages from the viewpoint of costs. In the case of the photocatalyst containing layer composed of the photocatalyst and the binder, an advantage that the photocatalyst containing layer is easily formed is produced. In the case of using, for example, a silane coupling agent or a polymer thereof as the binder or an additive, the plasma radiation in the present step causes a Si—C bond of the silane coupling agent or the polymer thereof to be broken, so that an OH group can be introduced into the bond-broken portion. In this way, the lyophilicity of the region where the photocatalyst containing layer is exposed, that is, the opening part can be made high. Thus, a wettability difference between the resin layer surface and the opening part surface can be made large.

The action mechanism of the photocatalyst, a typical example of which is titanium dioxide that will be detailed below, in the photocatalyst-containing layer is not necessarily clear, but would be as follows: carries generated by radiation of light react directly with adjacent chemical species or are combined with oxygen or active oxygen species generated in the presence of water, so as to change the chemical structure of organic materials. In the aspect, it appears that the carriers give an effect on the liquid repellent materials such as the above-mentioned residues, and the binder and other organic materials.

As the photocatalyst used in the present embodiment, those known as semiconductors, such as titanium dioxide (TiO₂), zinc oxide (ZnO), tin oxide (SnO₂), strontium titanate (SrTiO₃), tungsten oxide (WO₃), bismuth oxide (Bi₂O₃), and iron oxide (Fe₂O₃) can be presented. Apart from the semiconductors, metal complex or silver can be used as an example. In the present aspect, one or more kinds as a mixture can be selected and used from them.

According to the present embodiment, in particular, the titanium dioxide can be used preferably since it has high band gap energy, it is chemically stable without the toxicity, and it can be obtained easily. There are an anatase type and a rutile type in the titanium dioxides, and either can be used in the present embodiment, however, the anatase type titanium dioxide is preferable. The anatase type titanium dioxide has a 380 nm or less excitation wavelength.

As the anatase type titanium dioxide, for example, a hydrochloric acid deflocculation type anatase type titania sol (STS-02 (average particle diameter 7 nm) manufactured by ISHIHARA SANGYO KAISHA, LTD., ST-K01 manufactured by ISHIHARA SANGYO KAISHA, LTD.), or a nitric acid deflocculation type anatase type titania sol (TA-15 (average particle diameter 12 nm) manufactured by Nissan Chemical Industries, Ltd.) can be presented.

As the titanium oxide, visible ray responsible titanium oxide may be used. The visible ray responsible titanium oxide is excited by visible ray energy also. The method for making titanium oxide into such a visible ray responsible type may be a method of subjecting titanium oxide to nitriding treatment.

When titanium oxide (TiO₂) is subjected to nitriding treatment, a new energy level is generated inside the band gap of titanium oxide (TiO₂) so that the band gap becomes narrow. As a result, titanium oxide (TiO₂) can be also excited by a visible ray having a longer wavelength than the excitation wavelength of titanium oxide (TiO₂), which is usually 380 nm. This makes it possible to cause visible ray range wavelengths of energies radiated from various light sources to contribute to the excitation of titanium oxide (TiO₂). Thus, the sensitivity of titanium oxide can be made higher.

The nitriding treatment of titanium oxide referred to the aspect is such as a treatment of substituting some parts of oxygen sites in titanium oxide (TiO₂) crystal with nitrogen atoms; a treatment of doping spaces between crystal lattices of titanium oxide (TiO₂) with nitrogen atoms; or a treatment of arranging nitrogen atoms in grain boundaries of polycrystalline aggregates of titanium oxide (TiO₂) crystal.

The method for the nitriding treatment of titanium oxide (TiO₂) is not particularly limited, and is, for example, a method of subjecting fine particles of crystalline titanium oxide to thermal treatment at 700° C. in an ammonia atmosphere to dope the particles with nitrogen, and then using an inorganic binder, a solvent or the like to make the nitrogen-doped fine particles into a liquid dispersion.

With a smaller particle diameter of the photocatalyst, the photocalytic reaction can be generated more effectively, and thus it is preferable. An average particle diameter of 50 nm or less is preferable, and use of a photocatalyst of 20 nm or less is particularly preferable.

The method for forming the photocatalyst containing layer made only of the photocatalyst may be a vacuum film-forming method such as a sputtering, CVD, or vacuum evaporation method. When the photocatalyst containing layer is formed by the vacuum film forming method, the layer can be rendered a photocatalyst containing layer which is a homogeneous film and contains only the photocatalyst. This makes it possible to decompose and remove the liquid repellent materials present in the opening part partitioned by the resin layer in the present step or the liquid repellent material removing step which will be detailed later. Furthermore, the layer is made only of the photocatalyst, whereby it is possible to decompose and remove the liquid repellent materials more effectively than in the case of using a binder together.

Another example of the method for forming the photocatalyst containing layer made only of a photocatalyst, is the following method: in the case that the photocatalyst is, for example, titanium dioxide, amorphous titania is formed on the base material and next fired so as to phase-change the titania to crystalline titania. The amorphous titania used in this case can be obtained, for example, by hydrolysis or dehydration condensation of an inorganic salt of titanium, such as titanium tetrachloride or titanium sulfate, or hydrolysis or dehydration condensation of an organic titanium compound, such as tetraethoxytitanium, tetraisopropoxytitanium, tetra-n-propoxytitanium, tetrabutoxytitanium or tetramethoxytitanium, in the presence of an acid. Next, the resultant is fired at 400 to 500° C. so as to be denatured to anatase type titania, and fired at 600 to 700° C. so as to be denatured to rutile type titania.

In the case of using a binder, the binder is preferably a binder comprising a principal skeleton having such a high bonding energy that the principal skeleton is not decomposed by optical excitation of the photocatalyst, or the plasma radiation. An example thereof is an organopolysiloxane. The organopolysiloxane is an organopolysiloxane which is a silane coupling agent or a polymer thereof, and may be specifically the same as the one disclosed in JP-A No. 2000-249821.

When an organopolysiloxane is used as the binder in this way, the photocatalyst containing layer can be formed by dispersing the photocatalyst, the organopolysiloxane as the binder, and optional other additives into a solvent to prepare a coating solution, and then coating this coating solution onto a base material. The used solvent is preferably an alcoholic organic solvent such as ethanol, or isopropanol. The coating can be performed by a known coating method such as spin coating, spray coating, dip coating, roll coating or bead coating. In the case of using an ultraviolet curable component as the binder, the photocatalyst containing layer can be formed by curing treatment of radiating ultraviolet rays to the component.

An amorphous silica can be presented as the binder. The precursor of the amorphous silica is represented by the general formula: SiX₄. X is preferably a silicon compound such as a halogen, a methoxy group, an ethoxy group, an acetyl group, a silanol as a hydrolysis product thereof, or a polysiloxane having a 3,000 or less average molecular weight.

Specific example may be such as tetraethoxysilane, tetraisopropoxysilane, tetra-n-propoxysilane, tetrabutoxysilane or tetramethoxysilane. In this case, the photocatalyst containing layer can be formed by dispersing the amorphous silica precursor and particles of the photocatalyst homogeneously into a non-aqueous solvent, hydrolyzing the dispersion with water content in the air to form silanol on a base material, and dehydrating and polycondensing the silanol at room temperature. When the silanol is dehydrated and polycondensed at 100° C. or higher, the polymerization degree of the silanol increases so that the strength of the film surface can be improved. These binders may be used alone or in the form of a mixture of two or more thereof.

In the case of using the binder(s), the content by percentage of the photocatalyst in the photocatalyst containing layer may be from 5 to 60% by weight, and is preferably from 20 to 40% by weight. The thickness of the photocatalyst containing layer is preferably from 0.05 to 10 μm.

In the photocatalyst containing layer, a surfactant, an additive and the like can be used besides the photocatalyst and the binder. For example, substances as disclosed in JP-A No. 2001-074928 can be used.

(3) Base Material

Next, the base material used in the aspect is described. The base material is not particularly limited as long as the base material is a material on which the photocatalyst containing layer can be formed. The kind, the flexibility and the transparency thereof, and other points thereof are appropriately selected in accordance with the usage of the pattern formed body, and others. In the aspect, the base material may be made of an organic material, or an inorganic material. Specifically, the base material may be a resin film, or may be made of such as a glass, a ceramic, or a metal. The base material is preferably in a plate form.

The energy transparency of the base material is appropriately selected in accordance with the usage or kind of the pattern formed body, the direction along which energy is radiated in the liquid repellent material removing step, which will be detailed later, and others. When the energy is radiated, for example, from the side of the base material in the liquid repellent material removing step, it is necessary that the base material has transparency to the energy. On the other hand, when the energy is radiated from the side of the resin layer in the liquid repellent material removing step, it is not particularly necessary that the base material has transparency.

In the aspect, the surface of the base material may be subjected to surface treatment if necessary in order to prevent elution-out of alkali, give gas barrier property, and attain other purposes. An anchor layer or the like may be formed to improve, for example, the adhesive property between the base material and the photocatalyst containing layer.

(Method for Plasma Radiation)

Next, a method for radiating the plasma in the present step is described. This method is not particularly limited as long as the method is capable of radiating plasma using a fluorine compound as an introduction gas to make the upper face of the above-mentioned resin layer liquid repellent. Thus, the plasma may be radiated under a reduced pressure, or an atmospheric pressure.

Examples of the fluorine compound as the introduction gas used when the plasma is radiated include carbon fluoride (CF₄), carbon nitride (NF₃), sulfur fluoride (SF₆), CHF₃, C₂F₆, C₃F₈, and C₅F₈. Conditions for radiating the plasma are appropriately selected in accordance with a device for the radiation and the like.

In the present aspect, it is particularly preferred to radiate the plasma in the atmosphere pressure since no pressure-reducing device and so on is required, so that advantages are produced from the viewpoint of such as costs and production efficiency. Conditions for radiating the plasma in the atmosphere are as follows. For example, the power output therefore may be the same as used in an ordinary device for radiating plasma in the atmosphere pressure. The distance between the electrode for the plasma radiated at this time and the above-mentioned resin layer is preferably from about 0.2 to 20 mm, more preferably from about 1 to 5 mm. The flow rate of the fluorine compound used as the introduction gas is preferably from about 1 to 20 L/min. The flow rate of the nitrogen gas used at the same time as the fluorine compound is preferably from about 1 to 50 L/min. The transporting rate of the substrate at this time is preferably from about 0.5 to 2 m/min.

In the present step, the presence of the fluorine introduced in the resin layer can be checked by measuring the ratio of the fluorine element in all elements detected from the surface of the resin layer in analysis with an X-ray photoelectron spectral analyzer (XPS: ESCALAB 220i-XL) used for X-ray Photoelectron Spectroscopy (may referred to as ESCA (Electron Spectroscopy for Chemical Analysis)). The ratio of the fluorine introduced in the resin layer at this time is preferably 10% or more of all the elements detected from the surface of the resin layer.

In the present step, it is preferable that the plasma radiation is performed in such a manner that the contact angle of the resin layer with liquid becomes higher than that of the opening part partitioned by the resin layer with water by 1° or more. This makes it possible to use the difference in the contact angle with liquid between the resin layer and the opening part partitioned by the resin layer to a form functional part, such as a colored layer of a color filter, on the pattern formed body manufactured by the aspect.

In the present aspect in particular, the plasma is radiated so as to set the contact angle of liquid of the resin layer with water preferably to 61° or more, more preferably to 80° or more, even more preferably to 100° or more for the following reason. If the contact angle of the resin layer with liquid is small, the liquid repellency is insufficient; thus, at the time of a forming functional part, such as a colored layer of a color filter, on the opening part of the pattern formed body manufactured according to the aspect, a functional part forming coating solution for forming the functional part may unfavorably adhere onto the resin layer also.

The contact angle with respect to a liquid here is obtained from the results or a graph of the results of measuring (30 seconds after of dropping liquid droplets from a micro syringe) the contact angle with respect to water or liquids having equivalent contact angle to that of water using a contact angle measuring device (CA-Z type manufactured by Kyowa Interface Science, Co., Ltd).

b. Other Steps

The method for manufacturing the pattern formed body of the aspect may have any other step than the plasma radiating step if necessary. The aspect preferably has a liquid repellent material removing step of radiating energy to the opening part partitioned by the resin layer, thereby removing liquid repellent materials on the surface of the opening part. That is, the aspect may be a method for manufacturing a pattern formed body, comprising: a plasma radiating step of radiating plasma to a patterning substrate having a base material, a photocatalyst containing layer formed on the base material and containing at least a photocatalyst, and a resin layer formed on the base material and containing at least a resin, using a fluorine compound as an introduction gas to make the upper face of the resin layer liquid repellent; and a liquid repellent material removing step of radiating energy to the opening part partitioned by the resin layer to remove the liquid repellent materials on the surface of the opening part.

In the aspect, the photocatalyst containing layer is formed; thus, the photocatalyst in the photocatalyst containing layer can be excited by the energy radiation, so as to remove effectively liquid repellent materials, such as residues adhering onto the surface of the photocatalyst containing layer, and introduced fluorine.

The liquid repellent material removing step will be described in detail hereinafter.

(Liquid Repellent Material Removing Step)

The liquid repellent material removing step in the aspect is a step of radiating energy to the opening part partitioned by the resin layer, thereby removing the liquid repellent materials on the surface of the opening part. The above-mentioned liquid repellent materials are defined as materials which are present in the opening part partitioned by the resin layer and raise the contact angle between a functional part forming coating solution for forming a functional part and the opening part, and examples thereof include residues generated when the resin layer is formed and adhere onto the opening part surface, other organic materials, fluorine introduced into the residues through the plasma radiating step, and fluorine introduced into the photocatalyst containing layer. In the present step, the liquid repellent materials are removed by the action of the photocatalyst accompanying the energy radiation, thereby making it possible to make the upper surface of the resin layer have liquid repellency so as to coat the functional part forming coating solution into the opening part partitioned by the resin layer with a high precision.

In the step, the energy radiation is performed in such a manner that the liquid repellent materials in the opening part partitioned by the resin layer are removed to set the contact angle of the opening part surface with water preferably into 60° or less, more preferably into 40° or less, even more preferably into 20° or less. If the contact angle of the opening part with liquid is high, the upper face of the opening part in the pattern formed body manufactured according to the aspect also may repel the functional part forming coating solution for forming the functional part, so that the functional part is not easily formed with a high precision. The contact angle with water is a value measured by the above-mentioned method.

The method for the energy radiation in the liquid repellent material removing step is classified into the following 4 embodiments in accordance with the direction of the energy radiation and the like. The following will describe each of the embodiments.

### (1) First Embodiment

The first embodiment of the method for the energy radiation in the liquid repellent material removing step is first described. As illustrated in, for example, FIG. 2, the first embodiment is an embodiment of radiating energy to the entire surface from the side of the base material 1 after the plasma radiating step, thereby radiating the energy 8 to the opening part 7 partitioned by the resin layer 3 to remove liquid repellent materials on the opening part 7.

According to the embodiment, the resin layer is formed on the photocatalyst containing layer; therefore, even if energy is radiated to the entire surface from the side of the base material without using any photomask, the energy can be radiated only to the opening part partitioned by the resin layer. Thus, the liquid repellent materials on the opening part can be effectively removed by the action of the photocatalyst accompanying the energy radiation. At this time, in the opening part, the photocatalyst containing layer, which contains the photocatalyst, is exposed; thus, the liquid repellent materials on the opening part can be effectively removed by the action of the photocatalyst accompanying the energy radiation. The energy may be radiated to the entire surface from the base material side. However, the energy may be radiated using, for example, a photomask.

The energy radiation (exposure) referred to in the embodiment is a concept including radiation of any energy ray capable of removing the liquid repellent materials on the opening part from the photocatalyst containing layer. Thus, the energy radiation is not limited to visible ray radiation.

The energy used in the embodiment is not particularly limited as long as the energy is capable of exciting the photocatalyst in the photocatalyst containing layer. Usually, the wavelength of light used in this energy radiation is set to 400 nm or less, preferably 380 nm or less. As described above, a preferred example of the photocatalyst used in the photocatalyst containing layer is titanium dioxide; the energy for activating the photocatalyst action by the titanium dioxide is preferably light of the above-mentioned wavelength.

Examples of a light source that can be used in the energy radiation include a mercury lamp, a metal halide lamp, a xenon lamp, an excimer lamp, and various other light sources.

Besides the method of radiating the energy by use of the above-mentioned light source, it is possible to use a method of using a laser such as an excimer laser or a YAG laser to draw the energy in a pattern form.

The radiation quantity of the energy in the energy radiation is set to a radiation quantity necessary for decomposing and removing the liquid repellent materials on the opening part partitioned by the resin layer by such as the action of the photocatalyst in the photocatalyst containing layer.

At this time, it is preferable to radiate the energy while heating the photocatalyst containing layer since the sensitivity can be raised so that the liquid repellent materials can be effectively removed. Specifically, it is preferable to heat the layer within the range of 30 to 80° C.

### (2) Second Embodiment

Next, the second embodiment of the method for the energy radiation in the liquid repellent material removing step is described. As illustrated in, for example, FIG. 3, the second embodiment is an embodiment of preparing a photocatalyst processing layer side substrate 13 having a base body 11, and a photocatalyst processing layer 12 formed on the base body 11 and containing at least a photocatalyst, arranging the photocatalyst processing layer 12 and opening parts 7 oppositely to each other, and radiating energy 8 to the entire surface from the side of the base material 1 to remove liquid repellent materials present on the surface of the opening part 7 partitioned by the resin layer 3.

According to the embodiment, the energy is radiated in a state that the photocatalyst processing layer and the opening part are opposed to each other; therefore, the liquid repellent materials present on the opening part surface can be removed not only by the action of the photocatalyst in the photocatalyst containing layer formed at the side of the base material but also by the action of the photocatalyst in the photocatalyst processing layer, which accompanies the energy radiation. In the embodiment, it is preferable that the resin layer is rendered a light shielding part having light shielding property. In this case, the light shielding part is formed on the base material and the energy radiation is performed from the base material side; therefore, even if the energy is radiated to the entire surface, the energy can be radiated only to the opening part partitioned by the resin layer. Accordingly, the embodiment has an advantage that the liquid repellent material removing step can be effectively attained. When the resin layer has no light shielding property in the embodiment, it is preferable to use, for example, a photomask to cause the action of the photocatalyst to spread only to the opening part. Hereinafter, the photocatalyst processing layer side substrate used in the present step and the radiated energy will be described.

(Photocatalyst Processing Layer Side Substrate)

First, the photocatalyst processing layer side substrate used in the embodiment is described. This photocatalyst processing layer side substrate is not particularly limited as long as the substrate is a substrate having a base body and a photocatalyst processing layer formed on the base body.

The base body used in this photocatalyst processing layer side substrate is not particularly limited as long as the base body is a body on which the photocatalyst processing layer can be formed. The base body may be, for example, a flexible resin film, or a non-flexible member such as a glass substrate.

An anchor layer may be formed on the base body in order to improve the adhesive property between the base body surface and the photocatalyst processing layer, or prevent the base body from being deteriorated by the action of the photocatalyst. An example of this anchor layer is a film made of a silane or titanium based coupling agent, or a silica film formed by such as reactive sputtering or CVD.

The photocatalyst processing layer of the photocatalyst processing layer side substrate used in the embodiment may be equivalent to the above-mentioned photocatalyst containing layer. Thus, detailed description will not be described herein.

(Energy Radiation)

Next, the energy radiation in the embodiment is described. In the embodiment, the opening part partitioned by the resin layer and the photocatalyst processing layer of the photocatalyst processing layer side substrate are arranged so as to have a predetermined gap, and then energy is radiated thereto from the side of the base material. As described above, in the embodiment, it is preferable that the resin layer is rendered a light shielding part containing a light shielding material. In this case, energy is shielded in the region where the resin layer is formed; therefore, the energy can be radiated only to the opening parts, which is a region where the resin layer is not formed. Thus, the liquid repellent materials present in the opening part can be removed by the action of the photocatalyst containing layer and the photocatalyst processing layer, which accompanies the energy radiation.

The above-mentioned arrangement means a state that the opening part and the photocatalyst processing layer are arranged in such a manner that the action of the photocatalyst in the photocatalyst processing layer is substantially given to the opening part. Thus, the state is a state that the photocatalyst processing layer and the resin layer adhere closely to each other, or a state that the photocatalyst processing layer and the opening part are arranged to have a predetermined gap. This gap is preferably a gap having an interval of 200 μm or less.

The gap in the embodiment has an interval preferably from 0.2 to 10 μm, more preferably from 1 to 5 μm since the sensitivity of the photocatalyst is high so that the efficiency of removing the liquid repellent materials on the opening part becomes good. Such an interval range of the gap is in particular effective for small-area opening part, which makes it possible to control the interval with a particularly high accuracy.

Meanwhile, when the opening part has a large area, for example, an area of 300 mm×300 mm or a larger area are processed, it is very difficult to make fine gaps as described above between the photocatalyst processing layer side substrate and the opening part. Accordingly, when the opening part has a relatively large area, the interval of the gap is preferably from 10 to 100 μm, more preferably from 50 to 75 μm. When the interval is set into such a range, there are not caused a problem that the precision of the pattern falls, a problem that the sensitivity of the photocatalyst deteriorates so that the efficiency of removing the liquid repellent materials deteriorates, or other problems. Furthermore, produced is an advantageous effect that the liquid repellent materials in the opening part are uniformly removed without unevenness.

When energy is radiated to the opening part having a relatively large area in this way, it is preferable to set the interval of a gap in a unit for positioning the photocatalyst processing layer side substrate and the opening part in an energy radiating device into the range preferably from 10 to 200 μm, more preferably from 25 to 75 μm. When the set value is within such a range, the arrangement can be attained without deteriorating the sensitivity of the photocatalyst to a large extent.

When the photocatalyst processing layer and the opening part surface are arranged to be separated at the given interval in this way, active oxygen species generated by oxygen, water and the photocatalyst are easily desorbed. In other words, when the interval between the photocatalyst processing layer and the opening part is made narrower than the above-mentioned range, the active oxygen species are not easily desorbed so that the rate of removing the liquid repellent materials may be unfavorably made small. When they are arranged to have a larger interval than the above-mentioned range, the generated active oxygen species do not reach the opening part easily. In this case also, the rate of removing the liquid repellent materials may be unfavorably made small.

The method for arranging the photocatalyst processing layer and the opening part to make such a very narrow gap uniformly may be, for example, a method of using a spacer. When the space is used, a uniform gap can be made. Additionally, when the space is used, the active oxygen species generated by the action of the photocatalyst reach the base material surface at a high concentration without diffusing. Thus, the liquid repellent materials on the opening part can be effectively removed.

In the case of using the photocatalyst processing layer side substrate wherein the photocatalyst processing layer is formed on a flexible base body such as a flexible resin film, it is difficult to make a gap as described above. Thus, from the viewpoint of production efficiency and others, the photocatalyst processing layer and the resin layer are preferably arranged so as to be contacted by each other.

In the embodiment, it is sufficient that such an arrangement state of the photocatalyst processing layer side substrate is kept at shortest only during the energy radiation.

The energy used in the embodiment is not particularly limited as long as the energy makes it possible to excite the photocatalyst in the photocatalyst containing layer and the photocatalyst processing layer, and may be the same as described in the first embodiment. The radiation quantity of the energy in the energy radiation is set to a radiation quantity necessary for decomposing the liquid repellent materials present in the opening part partitioned by the resin layer by the action of the photocatalyst in the photocatalyst containing layer and the photocatalyst processing layer.

In the embodiment also, the sensitivity of the photocatalyst can be made high by performing the energy radiation while heating the photocatalyst containing layer or the photocatalyst processing layer. Thus, the liquid repellent materials can be favorably removed with a high efficiency. Specifically, it is preferable that the layer is heated within the range of 30 to 80° C.

### (3) Third Embodiment

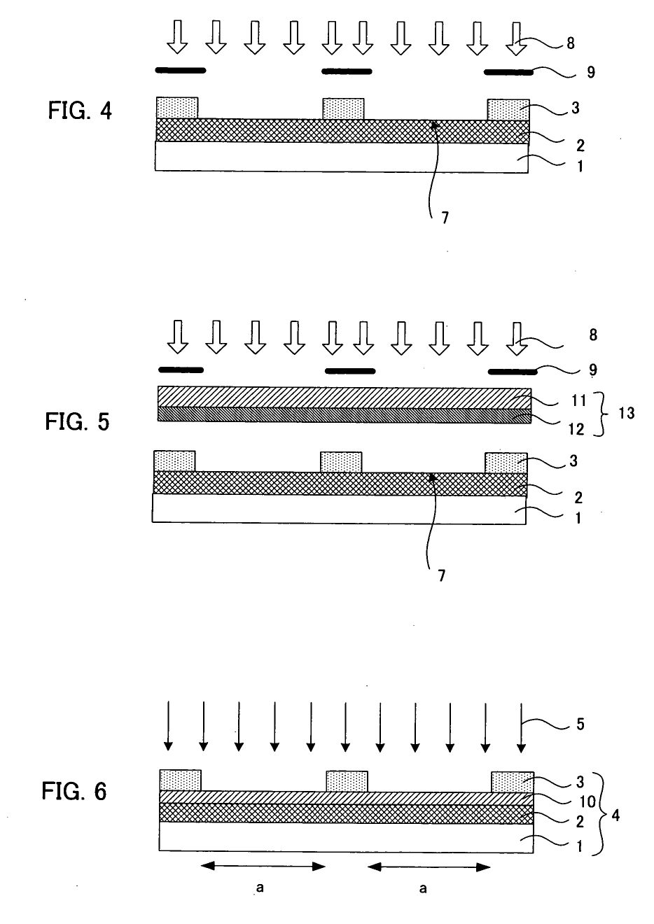

Next, the third embodiment of the method for the energy radiating in the liquid repellent material removing step is described. As illustrated in, for example, FIG. 4, the third embodiment of the method for the energy radiating in the present step is an embodiment of radiating energy 8 to the opening part 7 partitioned by the resin layer 3 from the side of the resin layer 3 of the base material 1, on which the resin layer 3 is formed, using, for example, a photomask 9, thereby removing liquid repellent materials present on the surfaces of the opening part 7.

According to the embodiment, the energy is radiated to the opening part partitioned by the resin from the side of the resin layer, whereby the liquid repellent materials present on the opening part surface can be removed by the action of the photocatalyst accompanying the energy radiation. The embodiment has an advantage that the liquid repellent materials on the opening part surface can be removed even if the base material does not transmit the energy.

The energy radiated in the embodiment is not particularly limited as long as the energy makes it possible to excite the photocatalyst in the photocatalyst containing layer to remove the liquid repellent materials present on the surfaces of the opening part partitioned by the resin layer. Thus, energy as described in the first embodiment can be used. In the embodiment, the energy can be radiated only to the opening part by energy radiation using, for example, a photomask, drawing radiation, or the like.

### (4) Fourth Embodiment

Next, the fourth embodiment of the method for the energy radiating in the liquid repellent material removing step is described. As illustrated in, for example, FIG. 5, the fourth embodiment of the method for the energy radiating in the step is an embodiment of preparing a photocatalyst processing layer side substrate 13 having a base body 11, and a photocatalyst processing layer 12 formed on the base body 11 and containing at least a photocatalyst, arranging the photocatalyst processing layer 12 and the resin layer 3 oppositely to each other, and radiating energy 8 thereto from the side of the photocatalyst processing layer side substrate 13, using, for example, a photomask 9, thereby removing liquid repellent materials present on the surface of the opening part 7 partitioned by the resin layer 3.

According to the embodiment, the liquid repellent materials on the opening part surfaces can be removed not only by the action of the photocatalyst in the photocatalyst containing layer formed at the side of the resin layer but also by the action of the photocatalyst in the photocatalyst processing layer. Thus, the present step can be effectively performed. Moreover, the embodiment has an advantage that the liquid repellent materials on the opening part surface can be removed even if the base material does not transmit the energy.

The energy radiated in the embodiment is not particularly limited as long as the energy makes it possible to excite the photocatalyst in the photocatalyst containing layer and the photocatalyst processing layer to remove the liquid repellent materials present on the surface of the opening part partitioned by the resin layer by the action of the photocatalyst. Thus, energy as described above in the first embodiment can be used. In the embodiment, the energy can be radiated only to the opening part by a method of radiating the energy into a pattern form by using a photomask or the like when the energy is radiated or by forming a photocatalyst processing layer side light shielding part in the photocatalyst processing layer side substrate, or a method of using a laser as described in the first embodiment to perform drawing radiation. The photocatalyst processing layer side light shielding part which can be formed in the photocatalyst processing layer side substrate can be formed by use of the same method and material for forming the above-mentioned resin layer, which is formed on the base material and containing the light shielding material. The photocatalyst processing layer side light shielding part may be formed on the photocatalyst processing layer, or between the base body and the photocatalyst processing layer. Furthermore, the light shielding part may be formed on the base body side opposite to the base body side on which the photocatalyst processing layer is formed.

The photocatalyst processing layer side substrate used in the embodiment, the method for arranging the photocatalyst processing layer side substrate, and others may be the same as in the second embodiment. Thus, detailed description thereof will not be described herein.

C. Usage of the Pattern Formed Body

The pattern formed body obtained in the aspect can be used for various purposes. The pattern formed body is preferably used to form a color filter wherein a colored layer is formed in the opening part. When the colored layer is formed by a jetting method such as an ink jet method, the color filter can be obtained with a high process efficiency. In this case, the used base material is a transparent base material which is transparent to visible rays. Specifically, the base material may be made of an inorganic material such as glass, or an organic material such as transparent resin. The resin layer is preferably rendered a light shielding part containing a light shielding material.

The pattern formed body obtained in the aspect is preferably used to form an organic EL element wherein an organic EL layer is formed in the opening part, or form a microlens wherein a lens is formed in the opening part. According to the aspect, the above-mentioned wettability difference is used to make the organic element layer or the lens into high quality with a high precision. Furthermore, the pattern formed body may be rendered a cell culturing substrate wherein the opening part is used to culture a cell.

2. Second Aspect

Next, the second aspect of the method of the invention for manufacturing a pattern formed body is described. The method for manufacturing the pattern formed body of the aspect has a plasma radiating step of radiating plasma to a patterning substrate having: a base material; a photocatalyst containing layer formed on the base material and containing at least a photocatalyst; an intermediate layer formed on the photocatalyst containing layer and containing a silane coupling agent or a polymer of the silane coupling agent; and a resin layer formed in a pattern form on the intermediate layer and containing at least a resin, wherein a fluorine compound used as an introduction gas to radiate the plasma to make the upper face of the resin layer liquid repellent.

As illustrated in, for example, FIG. 6, the method for manufacturing the pattern formed body of the aspect is a method of performing a plasma radiating step of radiating plasma 5 to a patterning substrate 4 having a base material 1, a photocatalyst containing layer 2 formed on the base material 1, an intermediate layer 10 formed on the photocatalyst containing layer 2, and a resin layer 3 formed in a pattern form on the intermediate layer 10, using a fluorine compound as an introduction gas, from the side of the resin layer 3, thereby manufacturing a pattern formed body.

According to the aspect, fluorine can be introduced into the resin layer by the plasma radiation so that the upper face of the resin layer can be made into a liquid repellent region. In a region where the resin layer is not formed, that is, a region where the intermediate layer is exposed to opening part, a Si—C bond of the intermediate layer exposed to the opening part is broken by the plasma radiation, so that an OH group can be introduced into the bond-broken portion. Accordingly, a difference in wettability between the resin layer surface and the surfaces of the opening part can be made large. This wettability difference is used to make it possible to manufacture a pattern formed body on which a functional part can be formed only in the opening part with a high precision.

In the aspect, the intermediate layer is formed; therefore, the aspect has an advantage of making good adhesive property between the photocatalyst containing layer and the resin layer, and between the photocatalyst containing layer and the functional part to be formed on the opening part, or others. The plasma radiating step and other steps in the method for manufacturing the pattern formed body of the aspect will be described in detail hereinafter.

(1) Plasma Radiating Step

The plasma radiating step in the aspect is a step of radiating plasma to a patterning substrate having: a base material; a photocatalyst containing layer formed on the base material and containing at least a photocatalyst; an intermediate layer formed on the photocatalyst containing layer and containing a silane coupling agent or a polymer of the silane coupling agent; and a resin layer formed in a pattern form on the intermediate layer and containing at least a resin, wherein a fluorine compound is used as an introduction gas to radiate the plasma to make the upper face of the resin layer liquid repellent. The patterning substrate and the plasma radiating method used in the aspect will be described hereinafter.

(Patterning Substrate)

The patterning substrate used in the present step is described herein. The patterning substrate is not particularly limited as long as the patterning substrate is a product which has a base material, a photocatalyst containing layer formed on the base material, an intermediate layer formed on the photocatalyst containing layer, and a resin layer formed in a pattern form on the intermediate layer, and which makes it possible that fluorine can be introduced onto the resin layer by plasma radiation that will be detailed later. In this patterning substrate, for example, between the base material and the photocatalyst containing layer may be formed an anchor layer for improving the adhesive property therebetween, or between the intermediate layer and the resin layer may be formed a primer layer for improving the adhesive property therebetween. The base material, the photocatalyst containing layer, and the resin layer may be the same as described in the item of the patterning substrate used in the first aspect. Thus, the intermediate layer will be described hereinafter.

The intermediate layer used in the aspect is a layer containing a silane coupling agent or a polymer of the silane coupling agent. In the aspect, a Si—C bond in the silane coupling agent or the polymer thereof is broken by the plasma radiation in the present step, so that the organic group is removed. An OH group or the like is introduced into the group-removed portion through water content, oxygen or the like in the atmosphere.

Specific examples of the silane coupling agent or the polymer thereof which is contained in the intermediate layer include the silane coupling agent or a polymer which is a hydrolysis or cohydrolysis condensation product of at least one compound represented by the following formula:
YₙSiX₍₄₋ₙ₎
(Here, Y is alkyl group, fluoroalkyl group, vinyl group, amino group, phenyl group, chloroalkyl group, isocyanate group, epoxy group or an organic group containing them; X is alkoxyl group, acetyl group or halogen; and n is an integer from 0 to 3). Here, the alkoxy group represented by X is preferably methoxy group, ethoxy group, propoxy group, or butoxy group. Moreover, the number of atoms of the entire organic group represented by Y is preferably in a range of 1 to 20, in particular, in a range of 5 to 10.

As the silane coupling agent, specifically, the following can be used: methyltrichlorosilane, methyltribromosilane, methyltrimethoxysilane, methyltriethoxysilane, methyltriisopropoxysilane, methyltri-t-butoxysilane; ethyltrichlorosilane, ethyltribromosilane, ethyltrimethoxysilane, ethyltriethoxysilane, ethyltriisopropoxysilane, ethyltri-t-butoxysilane; n-propyltrichlorosilane, n-propyltribromosilane, n-propyltrimethoxysilane, n-propyltriethoxysilane, n-propyltriisopropoxysilane, n-propyltri-t-butoxysilane; n-hexyltrichlorosilane, n-hexyltribromosilane, n-hexyltrimethoxysilane, n-hexyltrimethoxysilane, n-hexyltriisopropoxysilane, n-hexyltri-t-butoxysilane; n-decyltrichlorosilane, n-decyltribromosilane, n-decyltrimethoxysilane, n-decyltrimethoxysilane, n-decyltriisopropoxysilane, n-decyltri-t-butoxysilane; n-octadecyltrichlorosilane, n-octadecyltribromosilane, n-octadecyltrimethoxysilane, n-octadecyltriethoxysilane, n-octadecyltriisopropoxysilane, n-octadecyltri-t-butoxysilane; phenyltrichlorosilane, phenyltribromosilane, phenyltrimethoxysilane, phenyltriethoxysilane, phenyltriisopropoxysilane, phenyltri-t-butoxysilane; dimethoxydiethoxysilane; dimethyldichlorosilane, dimethyldibromosilane, dimethyldimethoxysilane, dimethyldiethoxysilane; diphenyldichlorosilane, diphenyldibromosilane, diphenyldimethoxysilane, diphenyldiethoxysilane; phenylmethyldichlorosilane, phenylmethyldibromosilane, phenylmethyldimethoxysilane, phenylmethyldiethoxysilane; trichlorohydrosilane, tribromohydrosilane, trimethoxyhydrosilane, triethoxyhydrosilane, triisopropoxyhydrosilane, tri-t-butoxyhydrosilane; vinyltrichlorosilane, vinyltribromosilane, vinyltrimethoxysilane, vinyltriethoxysilane, vinyltriisopropoxysilane, vinyltri-t-butoxysilane; γ-glycidoxypropylmethyldimethoxysilane, γ-glycidoxypropylmethyldiethoxysilane, γ-glycidoxypropyltrimethoxysilane, γ-glycidoxypropyltriethoxysilane, γ-glycidoxypropyltriisopropoxysilane, γ-glycidoxypropyltri-t-butoxysilane; γ-methacryloxypropylmethyldimethoxysilane, γ-methacryloxypropylmethyldiethoxysilane, γ-methacryloxypropyltrimethoxysilane, γ-methacryloxypropyltriethoxysilane, γ-methacryloxypropyltriisopropoxysilane, γ-methacryloxypropyl tri-t-butoxysilane; γ-aminopropylmethyldimethoxysilane, γ-aminopropylmethyldiethoxysilane, γ-aminopropyltrimethoxysilane, γ-aminopropyltriethoxysilane, γ-aminopropyltriisopropoxysilane, γ-aminopropyltri-t-butoxysilane; γ-mercaptopropylmethyldimethoxysilane, γ-mercaptopropylmethyldiethoxysilane, γ-mercaptopropyltrimethoxysilane, γ-mercaptopropyltriethoxysilane, γ-mercaptopropyltriisopropoxysilane, γ-mercaptopropyltri-t-butoxysilane; β-(3,4-epoxycyclohexyl)ethyltrimethoxysilane, β-(3,4-epoxycyclohexyl)ethyltriethoxysilane; partially hydrolyzed products thereof; and mixture thereof.

The compound containing a fluoroalkyl group is exemplified below. Any compound that is generally known as a fluorine-based silane coupling agent may be used.
CF₃(CF₂)₃CH₂CH₂Si(OCH₃)₃;
CF₃(CF₂)₅CH₂CH₂Si(OCH₃)₃;
CF₃(CF₂)₇CH₂CH₂Si(OCH₃)₃;
CF₃(CF₂)₉CH₂CH₂Si(OCH₃)₃;
(CF₃)₂CF(CF₂)₄CH₂CH₂Si(OCH₃)₃;
(CF₃)₂CF(CF₂)₆CH₂CH₂Si(OCH₃)₃;
(CF₃)₂CF(CF₂)₈CH₂CH₂Si(OCH₃)₃;
CF₃(C₆H₄)C₂H₄Si(OCH₃)₃;
CF₃(CF₂)₃(C₆H₄)C₂H₄Si(OCH₃)₃;
CF₃(CF₂)₅(C₆H₄)C₂H₄Si(OCH₃)₃;
CF₃(CF₂)₇(C₆H₄)C₂H₄Si(OCH₃)₃;
CF₃(CF₂)₃CH₂CH₂SiCH₃(OCH₃)₂;
CF₃(CF₂)₅CH₂CH₂SiCH₃(OCH₃)₂;
CF₃(CF₂)₇CH₂CH₂SiCH₃(OCH₃)₂;
CF₃(CF₂)₉CH₂CH₂SiCH₃(OCH₃)₂;
(CF₃)₂CF(CF₂)₄CH₂CH₂SiCH₃(OCH₃)₂;
(CF₃)₂CF(CF₂)₆CH₂CH₂Si CH₃(OCH₃)₂;
(CF₃)₂CF(CF₂)₈CH₂CH₂Si CH₃(OCH₃)₂;
CF₃(C₆H₄)C₂H₄SiCH₃(OCH₃)₂;
CF₃(CF₂)₃(C₆H₄)C₂H₄SiCH₃(OCH₃)₂;
CF₃(CF₂)₅(C₆H₄)C₂H₄SiCH₃(OCH₃)₂;
CF₃(CF₂)₇(C₆H₄)C₂H₄SiCH₃(OCH₃)₂;
CF₃(CF₂)₃CH₂CH₂Si(OCH₂CH₃)₃;
CF₃(CF₂)₅CH₂CH₂Si(OCH₂CH₃)₃;
CF₃(CF₂)₇CH₂CH₂Si(OCH₂CH₃)₃;
CF₃(CF₂)₉CH₂CH₂Si(OCH₂CH₃)₃;
CF₃(CF₂)₇SO₂N(C₂H₅)C₂H₄CH₂Si(OCH₃)₃.

When the intermediate layer consists only of the silane coupling agent or a polymer thereof, the formation of the intermediate layer can be attained by applying the above-mentioned material, which is dispersed in such as a solvent if necessary, onto a base material in a known coating method such as spin coating, spray coating, dip coating, roll coating or bead coating. At this time, the intermediate layer made of the polymer may be formed by hydrolyzing the silane coupling agent with water content in the air to produce a silanol, and then subjecting the silanol to dehydrating polycondensation. The dehydrating polycondensation may be conducted at room temperature. When the polycondensation is conducted at 100° C. or higher, the polymerization degree of the silanol increases, so that the strength of the film surface can be improved.

When the intermediate layer contains a binder, the material used as the binder in the intermediate layer is preferably a material which does not undergo decomposition or the like by plasma radiation. For example, an amorphous silica precursor may be used. This amorphous silica precursor is a silicon compound represented by the general formula SiX₄ wherein X is such as halogen, methoxy group, ethoxy group or acetyl group, silanol which is a hydrolyzate thereof, or polysiloxane having an average molecular weight of 3000 or less.

Specific examples thereof include tetraethoxysilane, tetraisopropoxysilane, tetra-n-propoxysilane, tetrabutoxysilane, and tetramethoxysilane. In this case, the intermediate layer can be formed by dispersing, for example, the amorphous silica precursor and the silane coupling agent or the polymer thereof homogeneously into a non-aqueous solvent, applying the dispersion onto a base material, hydrolyzing the applied dispersion with water content in the air in the same manner as described above to produce a silanol, and then subjecting the silanol to dehydrating polycondensation. In terms of the binder, only one kind thereof or a mixture of two or more kinds thereof may be used.

In the embodiment, the film thickness of the intermediate layer, which is appropriately selected in accordance with the kind of the intermediate layer, is usually 1 μm or less, preferably 0.1 μm or less. The lower limit of the film thickness of the intermediate layer may be the thickness of a monomolecular membrane made of the above-mentioned material(s) since it is sufficient that the layer containing the material(s) is homogeneously formed.

(Method for Plasma Radiation)

The method for plasma radiation in the present step is not particularly limited as long as the method makes it possible to use a fluorine compound as an introduction gas to radiate plasma to make the upper face of the resin layer liquid repellent and make a region where the intermediate layer is exposed lyophilic. The plasma may be radiated under a reduced pressure or under an atmospheric pressure. This method for plasma radiation may be the same as in the first aspect. Thus, detailed description thereof will not be described herein.

In the present step, the presence of the fluorine introduced in the resin layer can be checked by measuring the ratio of the fluorine element in all elements detected from the surface of the resin layer in analysis with an X-ray photoelectron spectral analyzer (XPS: ESCALAB 220i-XL) used for X-ray Photoelectron Spectroscopy (may referred to as ESCA (Electron Spectroscopy for Chemical Analysis)). The ratio of the fluorine introduced in the resin layer at this time is preferably 10% or more of all the elements detected from the surface of the resin layer.

In the present step in particular, the fluorine is introduced so as to set the contact angle of liquid of the resin layer with water preferably to 61° or more, more preferably to 80° or more, even more preferably to 100° or more for the following reason. If the contact angle of the resin layer with liquid is small, the liquid repellency is insufficient; thus, at the time of forming a functional element using the pattern formed body of the present aspect, a functional part forming coating solution for forming a functional part may unfavorably adhere onto the resin layer also.

The contact angle of the region where the intermediate layer is exposed with liquid, specifically, water, is preferably 60° or less, more preferably 40° or less, even more preferably 20° or less. If the contact angle of the region where the intermediate layer is exposed with liquid is high, at the time of forming the functional part on the pattern formed body of the aspect, the region may repel a functional part forming coating solution for functional part formation. Thus, the functional part may not be easily formed with a high precision. The contact angle with liquid is measured by the above-mentioned method.

b. Other Steps

The method for manufacturing pattern formed body of the aspect may have any step other than the plasma radiating step if necessary. In the aspect, the method may have a liquid repellent material removing step of radiating energy to the opening part partitioned by the resin layer, thereby removing liquid repellent material on the surface of the opening part. For example, if residues generated when the resin layer is formed or others adhere onto the opening part surface, the wettability difference between the resin layer and the opening part is small. Thus, it becomes difficult that the wettability difference is used to form a functional part with a high precision. Thus, the action of the photocatalyst accompanying the energy radiation is given to the opening part to remove the liquid repellent materials, such as the residues present on the opening part surface. In this way, the wettability difference between the opening part and the resin layer can be made larger. Even if the organic groups remain in the intermediate layer after the plasma radiating step, these can be removed by the action of the photocatalyst accompanying the energy radiation, so as to give an advantage that the opening part surface can be made more lyophilic.

The liquid repellent material removing step in the aspect may be the same as in the first aspect. Thus, detailed description thereof will not be described herein.

3. Other Aspects

The method for manufacturing pattern formed body of the invention includes the following aspects also.

A different aspect of the method for manufacturing the pattern formed body comprising: a plasma radiating step of radiating plasma to a patterning substrate having a base material, a photocatalyst containing layer formed on the base material and containing at least a photocatalyst, and a light shielding part formed on the photocatalyst containing layer and containing at least a light shielding material and a resin, wherein a fluorine compound is used as an introduction gas to radiate the plasma to make the upper face of the light shielding part liquid repellent; and a liquid repellent material removing step of radiating energy to an opening part partitioned by the light shielding part, thereby removing liquid repellent materials on the surface of the opening part.

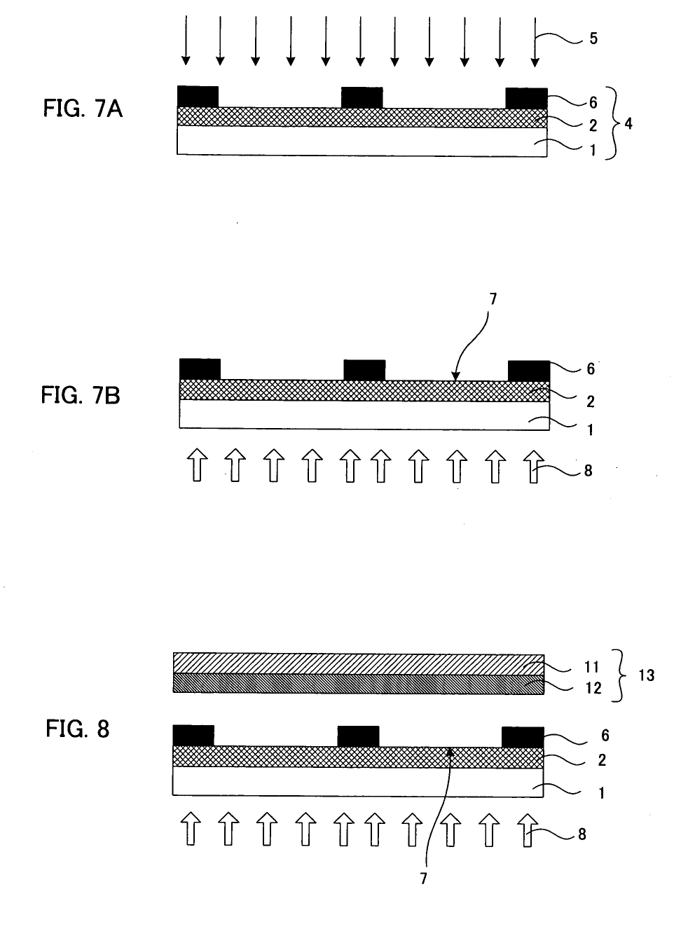

As illustrated in FIGS. 7A and 7B, the method for manufacturing the pattern formed body of the aspect has a plasma radiating step (FIG. 7A) of radiating plasma 5 to a patterning substrate 4 having a base material 1, a photocatalyst containing layer 2 formed on the base material 1 and, a light shielding part 6 formed on the photocatalyst containing layer 2; and a liquid repellent material removing step (FIG. 7B) of radiating energy 8 to an opening part 7 partitioned by the light shielding part 6, thereby removing liquid repellent materials present on the surface of the opening part 7.

When a fluorine compound is used as an introduction gas to radiate plasma, fluorine can be introduced into an organic material so that the surface thereof can be made liquid repellent. According to the aspect, therefore, plasma is radiated in the plasma radiating step, whereby the upper face of the light shielding part can be rendered a liquid repellent region. In general, however, residues generated when the light shielding part is formed, and so forth are present on the opening part. Thus, in the plasma radiating step, fluorine is also introduced into the residues and so forth. Accordingly, liquid repellent region may be formed not only in the light shielding part but also on the opening part.

In the aspect, therefore, after the plasma radiating step, performed is a liquid repellent material removing step of radiating energy to the opening part partitioned by the light shielding part, thereby removing such as the residues adhered onto the opening part, and the introduced fluorine. Since the photocatalyst containing layer is formed in the aspect, the energy radiation makes it possible to excite the photocatalyst in the photocatalyst containing layer to remove effectively the residues adhered onto the photocatalyst containing layer surface, the introduced fluorine, and other liquid repellent materials. Accordingly, the upper face of the light shielding part can be used as a liquid repellent region and the upper face of the opening part can be used as a lyophilic region. The wettability difference between the upper face of the light shielding part and the upper face of the opening part is used to make it possible to manufacture a pattern formed body on which various functional parts can be formed with a high precision. Each of the steps in the method for manufacturing the pattern formed body of the aspect will be described in detail hereinafter.

a. Plasma radiating step

First, the plasma radiating step in the aspect is described. This plasma radiating step is a step of radiating plasma to a patterning substrate having: a base material; a photocatalyst containing layer formed on the base material and containing at least a photocatalyst; and a light shielding part formed on the photocatalyst containing layer and containing at least a light shielding material and a resin, wherein a fluorine compound is used as an introduction gas to radiate the plasma to make the upper face of the light shielding part liquid repellent.

As will be detailed later, as the light shielding part of the patterning substrate, a part containing a light shielding material and a resin is used in the aspect; therefore, when plasma is radiated through the present step, fluorine can be introduced onto the light shielding part so that the upper face of the light shielding part can be used as a region having liquid repellency. Each of the patterning substrate and the method for the plasma radiation used in the present step will be described hereinafter.

(Patterning Substrate)

First, the patterning substrate used in the step is described. The patterning substrate is not particularly limited as long as the patterning substrate is a product which has a base material, a photocatalyst containing layer formed on the base material, and a light shielding part formed on the photocatalyst containing layer, and which makes it possible that fluorine is introduced onto the light shielding part by plasma radiation that will be detailed later. In this patterning substrate, for example, between the base material and the photocatalyst containing layer may be formed an anchor layer for improving the adhesive property therebetween, and between the photocatalyst containing layer and the light shielding part may be formed a primer layer for improving the adhesive property therebetween. Each of the constituents of the patterning substrate used in the step will be described hereinafter.

(1) Light Shielding Part

The light shielding part used in the aspect is a part containing a light shielding material and a resin. The shape and film thickness thereof, and other points thereof are appropriately selected in accordance with the usage of the pattern formed body, the kind of the light shielding part, and others.

In the aspect, the method for forming the light shielding part may be, for example, a method of forming a layer wherein light shielding particles made of carbon fine particles, metal oxide, inorganic pigment, organic pigment or the like are incorporated into a resin binder into a pattern form. The resin binder to be used may be: a single or mixture made of one or more selected from resins such as polyimide resin, acrylic resin, epoxy resin, polyacrylamide, polyvinyl alcohol, gelatin, casein and cellulose; a photosensitive resin; an O/W emulsion type resin composition such as a product obtained by emulsifying a reactive silicone; or the like. The method for patterning this resin light shielding part may be an ordinarily-used method, such as photolithography or printing.

In the aspect, the light shielding part may be formed by thermal transfer process. The thermal transfer process for forming the light shielding part is ordinarily a process of: arranging, on a base material, a thermal transfer sheet wherein a photothermally converting layer and a light shielding part transferring layer are formed on a single face of a transparent film substrate; and radiating energy to a region where the light shielding part is to be formed, thereby transferring the light shielding part transferring layer onto the base material so as to form the light shielding part.

The light shielding part transferred by the thermal transfer process is usually composed of a light shielding material and a binder. As the light shielding material, inorganic particles made of such as carbon black or titanium black can be used. The diameter of such light shielding material particles is preferably from 0.01 to 1.0 μm, more preferably from 0.03 to 0.3 μm.

The binder is preferably rendered a resin composition having thermal plasticity and thermosetting property. The binder is preferably composed of: a resin material having a thermosetting functional group and a softening point ranging from 50 to 150° C., in particular from 60 to 120° C.; a hardener; and the like. A specific example of such a material is a combination of an epoxy compound or epoxy resin having, in a single molecule thereof, two or more epoxy groups with a latent hardener thereof. The latent hardener for the epoxy resin may be a hardener which does not have reactivity with an epoxy group up to a predetermined temperature but has a molecular structure variable to have reactivity with the epoxy group when the hardener is heated so that the temperature of the hardener reaches the activation temperature thereof. A specific example thereof may be a neutral salt, a complex, a block compound, a high melting point compound, or a micro-encapsulated product of an acidic or basic compound having reactivity with an epoxy resin. The light shielding part may have, besides the above-mentioned materials, a releasing agent, an adhesion aid, an antioxidant, a dispersing agent or the like.

(2) Photocatalyst Containing Layer

Next, the photocatalyst containing layer of the patterning substrate used in the present step is described. This photocatalyst containing layer is not particularly limited as long as the layer contains at least a photocatalyst and makes it possible to remove liquid repellent materials present in the opening part partitioned by the resin layer, which are present on the photocatalyst containing layer, by the action of the photocatalyst accompanying energy radiation in the liquid repellent material removing step that will be detailed later. This photocatalyst containing layer may be, for example, a layer made only of the photocatalyst, or a layer containing the photocatalyst and a binder. When the photocatalyst containing layer contains the binder also, fluorine may be introduced thereinto by plasma radiation which will be detailed later. However, through the liquid repellent material removing step, which will be detailed later, the fluorine and the like can be removed by the action of the photocatalyst accompanying energy radiation.

When the photocatalyst containing layer is made only of the photocatalyst, the efficiency of removing the liquid repellent materials present in the opening part on the base material is improved, so as to make the time for the processing short and give advantages from the viewpoint of costs and others. In the case of the photocatalyst containing layer composed of the photocatalyst and the binder, an advantage that the photocatalyst containing layer is easily formed is produced.

The mechanism of the action of the photocatalyst, a typical example of which is titanium dioxide, which will be detailed later, in the photocatalyst containing layer is not necessarily evident. However, it appears that carriers generated by the radiation of light causes a change of the chemical structure of an organic material by direct reaction with a compound in the vicinity of the carries or by the action of active oxygen species generated in the presence of oxygen or water. In the aspect, the carries would produce an effect on the liquid repellent materials such as the residues, and the binder or other organic materials.

As the photocatalyst used in the present aspect, those known as photo semiconductors, such as titanium dioxide (TiO₂), zinc oxide (ZnO), tin oxide (SnO₂), strontium titanate (SrTiO₃), tungsten oxide (WO₃), bismuth oxide (Bi₂O₃), and iron oxide (Fe₂O₃) can be presented, and one or two or more kinds as a mixture can be selected and used from them.

According to the present aspect, in particular, a titanium dioxide can be used preferably since it has high band gap energy, it is chemically stable without the toxicity, and it can be obtained easily. There are an anatase type and a rutile type in the titanium dioxides, and either can be used in the present aspect, however, the anatase type titanium dioxide is preferable. The anatase type titanium dioxide has a 380 nm or less excitation wavelength.

As the anatase type titanium dioxide, for example, a hydrochloric acid deflocculation type anatase type titania sol (STS-02 (average particle diameter 7 nm) manufactured by ISHIHARA SANGYO KAISHA, LTD., ST-K01 manufactured by ISHIHARA SANGYO KAISHA, LTD.), or a nitric acid deflocculation type anatase type titania sol (TA-15 (average particle diameter 12 nm) manufactured by Nissan Chemical Industries, Ltd.) can be presented.

As the titanium oxide, visible ray responsible titanium oxide may be used. The visible ray responsible titanium oxide is excited also by visible ray energy. The method for making titanium oxide into such a visible ray responsible type may be a method of subjecting titanium oxide to nitriding treatment.

When titanium oxide (TiO₂) is subjected to nitriding treatment, a new energy level is generated inside the band gap of titanium oxide (TiO₂) so that the band gap becomes narrow. As a result, titanium oxide (TiO₂) can also be excited by a visible ray having a longer wavelength than the excitation wavelength of titanium oxide (TiO₂), which is usually 380 nm. This makes it possible to cause visible ray range wavelengths of energies radiated from various light sources to contribute to the excitation of titanium oxide (TiO₂). Thus, the sensitivity of titanium oxide can be made higher.

The nitriding treatment of titanium oxide referred to the aspect is, for example, a treatment of substituting some parts of oxygen sites in titanium oxide (TiO₂) crystal with nitrogen atoms; a treatment of doping spaces between crystal lattices of titanium oxide (TiO₂) with nitrogen atoms; or a treatment of arranging nitrogen atoms in grain boundaries of polycrystalline aggregates of titanium oxide (TiO₂) crystal.

The method for the nitriding treatment of titanium oxide (TiO₂) is not particularly limited, and is, for example, a method of subjecting fine particles of crystalline titanium oxide to thermal treatment at 700° C. in an ammonia atmosphere to dope the particles with nitrogen, and then using an inorganic binder, a solvent or the like to make the nitrogen-doped fine particles into a liquid dispersion.

With a smaller particle diameter of the photocatalyst, the photocalytic reaction can be generated more effectively, and thus it is preferable. An average particle diameter of 50 nm or less is preferable, and use of a photocatalyst of 20 nm or less is particularly preferable.

The method for forming the photocatalyst containing layer made only of the photocatalyst may be a vacuum film-forming method such as a sputtering, CVD, or vacuum evaporation method. When the photocatalyst containing layer is formed by the vacuum film forming method, the layer can be rendered a photocatalyst containing layer which is a homogeneous film and contains only the photocatalyst. This makes it possible to decompose and remove the liquid repellent materials present in the opening part partitioned by the light receiving part in the liquid repellent material removing step which will be detailed later. Furthermore, the layer is made only of the photocatalyst, whereby it is possible to decompose and remove the liquid repellent materials more effectively than in the case of using a binder together.

Another example of the method for forming the photocatalyst containing layer made only of a photocatalyst, is the following method: in the case that the photocatalyst is, for example, titanium dioxide, amorphous titania is formed on the base material and next fired so as to phase-change the titania to crystalline titania. The amorphous titania used in this case can be obtained, for example, by hydrolysis or dehydration condensation of an inorganic salt of titanium, such as titanium tetrachloride or titanium sulfate, or hydrolysis or dehydration condensation of an organic titanium compound, such as tetraethoxytitanium, tetraisopropoxytitanium, tetra-n-propoxytitanium, tetrabutoxytitanium or tetramethoxytitanium, in the presence of an acid. Next, the resultant is fired at 400 to 500° C. so as to be denatured to anatase type titania, and fired at 600 to 700° C. so as to be denatured to rutile type titania.

In the case of using a binder, the binder is preferably a binder having a principal skeleton having such a high bonding energy that the principal skeleton is not decomposed by optical excitation of the photocatalyst, or the plasma radiation. An example thereof is an organopolysiloxane.

When an organopolysiloxane is used as the binder in this way, the photocatalyst containing layer can be formed by dispersing the photocatalyst, the organopolysiloxane as the binder, and optional other additives into a solvent to prepare a coating solution, and then coating this coating solution onto a base material. The used solvent is preferably an alcoholic organic solvent such as ethanol, or isopropanol. The coating can be performed by a known coating method such as spin coating, spray coating, dip coating, roll coating or bead coating. In the case of using an ultraviolet curable component as the binder, the photocatalyst containing layer can be formed by curing treatment of radiating ultraviolet rays to the component.

An amorphous silica can be presented as the binder. The precursor of the amorphous silica is represented by the general formula: SiX₄. X is preferably a silicon compound such as halogen, methoxy group, ethoxy group, acetyl group, silanol as a hydrolysis product thereof, or a polysiloxane having a 3,000 or less average molecular weight.

Specific example may be such as tetraethoxysilane, tetraisopropoxysilane, tetra-n-propoxysilane, tetrabutoxysilane or tetramethoxysilane. In this case, appropriately selected in accordance with the usage of the pattern formed body, and others. Specifically, the base material may be a resin film, or may be made of a glass, a ceramic, a metal or the like. The base material is preferably in a plate form.

The energy transparency of the base material is appropriately selected in accordance with the usage or kind of the pattern formed body, the direction along which energy is radiated in the liquid repellent material removing step, which will be detailed later, and others. When the energy is radiated, for example, from the side of the base material in the liquid repellent material removing step, it is necessary that the base material has transparency to the energy. On the other hand, when the energy is radiated from the side of the light receiving part in the liquid repellent material removing step, it is not particularly necessary that the base material has transparency.

In the aspect, the surface of the base material may be subjected to surface treatment if necessary in order to prevent elution-out of alkali, give gas barrier property, and attain other purposes. An anchor layer or the like may be formed to improve, for example, the adhesive property between the base material and the photocatalyst containing layer.

(Method for Plasma Radiation)

Next, method for radiating the plasma in the present the photocatalyst containing layer can be formed by dispersing the amorphous silica precursor and particles of the photocatalyst homogeneously into a non-aqueous solvent, hydrolyzing the dispersion with water content in the air to form silanol on a base material, and dehydrating and polycondensing the silanol at room temperature. When the silanol is dehydrated and polycondensed at 100° C. or higher, the polymerization degree of the silanol increases so that the strength of the film surface can be improved. These binders may be used alone or in the form of a mixture of two or more thereof.

In the case of using the binder(s), the content by percentage of the photocatalyst in the photocatalyst containing layer may be from 5 to 60% by weight, and is preferably from 20 to 40% by weight. The thickness of the photocatalyst containing layer is preferably from 0.05 to 10 μm.

In the photocatalyst containing layer, a surfactant, an additive and the like can be used besides the photocatalyst and the binder. For example, substances as disclosed in JP-A No. 2001-074928 can be used.

(3) Base Material

Next, the base material used in the aspect is described. The base material is not particularly limited as long as the base material is a material on which the photocatalyst containing layer can be formed. The kind, the flexibility and the transparency thereof, and other points thereof are step is described. This method is not particularly limited as long as the method is capable of radiating plasma using a fluorine compound as an introduction gas to make the upper face of the above-mentioned light shielding part liquid repellent. Thus, the plasma may be radiated under a reduced pressure, or an atmospheric pressure.

Examples of the fluorine compound as the introduction gas used when the plasma is radiated include carbon fluoride (CF₄), carbon nitride (NF₃), sulfur fluoride (SF₆), CHF₃, C₂F₆, C₃F₈ and C₅F₈. Conditions for radiating the plasma are appropriately selected in accordance with a device for the radiation and the like.

In the aspect, it is particularly preferred to radiate the plasma in the atmosphere pressure since no pressure-reducing device and so on is required, so that advantages are produced from the viewpoint of such as costs and production efficiency. Conditions for radiating the plasma in the atmosphere are as follows. For example, the power output therefore may be the same as used in an ordinary device for radiating plasma in the atmosphere pressure. The distance between the electrode for the plasma radiated at this time and the above-mentioned light receiving part is preferably from about 0.2 to 20 mm, more preferably from about 1 to 5 mm. The flow rate of the fluorine compound used as the introduction gas is preferably from about 1 to 20 L/min. The flow rate of the nitrogen gas used at the same time as the fluorine compound is preferably from about 1 to 50 L/min. The transporting rate of the substrate at this time is preferably from about 0.5 to 2 m/min.

In the present step, it is preferable that the plasma radiation is performed in such a manner that the contact angle of the light receiving part with liquid becomes higher than that of the opening part partitioned by the light receiving part with water by 1° or more. This makes it possible to use the difference in the contact angle with liquid between the light receiving part and the opening part partitioned by the light receiving part to form a functional part, such as a colored layer of a color filter, on the pattern formed body manufactured by the aspect.

In the aspect, the plasma radiation is performed so as to set the contact angle of the light shielding part with liquid as follows: preferably, the contact angle with liquid having a surface tension of 40 mN/m becomes 10° or more; more preferably, the contact angle with liquid having a surface tension of 30 mN/m becomes 10° or more; and even more preferably, the contact angle with liquid having a surface tension of 20 mN/m becomes 10° or more. It is also preferable that the contact angle with pure water is 11° or more. If the contact angle of the light receiving part with liquid is small, the liquid repellency is insufficient; thus, at the time of forming the functional part, such as a colored layer of a color filter, on the opening part of the pattern formed body manufactured according to the aspect, a functional part forming coating solution for forming the functional part may unfavorably adhere onto the light receiving part also.

The contact angle with respect to a liquid here is obtained from the results or a graph of the results of measuring (30 seconds after of dropping liquid droplets from a micro syringe) the contact angle with respect to water or liquids having equivalent contact angle to that of water using a contact angle measuring device (CA-Z type manufactured by Kyowa Interface Science, Co., Ltd). Moreover, at the time of the measurement, as the liquids having the various surface tensions, wetting index standard solution manufactured by JUNSEI CHEMICAL CO., LTD. were used.

B. Liquid Repellent Material Removing Step

Next, the liquid repellent material removing step in the present aspect will be explained. The liquid repellent material removing step in the aspect is a step of radiating energy to the opening part partitioned by the light shielding part, thereby removing the liquid repellent materials on the surface of the opening part. The above-mentioned liquid repellent materials are defined as materials which are present in the opening part partitioned by the light shielding part and raise the contact angle between a functional part forming coating solution for forming a functional part and the opening part, and examples thereof include residues generated when the light shielding part is formed and adhere onto the opening part surface, other organic materials, fluorine introduced into the residues through the plasma radiating step, and fluorine introduced into the photocatalyst containing layer. In the present step, the liquid repellent materials are removed by the action of the photocatalyst accompanying the energy radiation, thereby making it possible to make only the upper surface of the light shielding part have liquid repellency so as to coat the functional part forming coating solution into the opening part partitioned by the light shielding part with a high precision.

In the present step, the energy radiation is performed in such a manner that the liquid repellent materials on the opening part partitioned by the light shielding part are removed so as to set the contact angle of the surfaces of the opening part with liquid as follows: preferably, the contact angle with liquid having a surface tension of 40 mN/m becomes less than 9°; more preferably, the contact angle with liquid having a surface tension of 50 mN/m becomes 10° or less; and even more preferably, the contact angle with liquid having a surface tension of 60 mN/m becomes 10° or less. It is also preferable that the energy radiation is performed to set the contact angle with pure water to 10° or less. If the contact angle of the opening part with liquid is high, the uppers of the opening part in the pattern formed body manufactured according to the aspect also may repel the functional part forming coating solution for forming the functional part, so that the functional part is not easily formed with a high precision. The contact angle with water is a value measured by the above-mentioned method.

The method for the energy radiation in the liquid repellent material removing step is classified into the following 4 embodiments in accordance with the direction of the energy radiation and the like. The following will describe each of the embodiments.

### (1) First Embodiment

The first embodiment of the method for the energy radiating in the liquid repellent material removing step is first described. As illustrated in, for example, FIG. 7B, the first embodiment is an embodiment of radiating energy 8 to the entire surface from the side of the base material 1 after the plasma radiating step, thereby radiating the energy 8 to the opening part 7 partitioned by the light shielding part 6 to remove liquid repellent materials on the opening part 7.

According to the embodiment, the light shielding part is formed; therefore, even if energy is radiated to the entire surface from the side of the base material without using any photomask, the energy can be radiated only to the opening part partitioned by the light shielding part. Thus, the liquid repellent materials on the opening part can be effectively removed. At this time, in the opening part, the photocatalyst containing layer, which contains the photocatalyst, is exposed; thus, the liquid repellent materials and others on the opening part can be effectively removed by the action of the photocatalyst accompanying the energy radiation.

The energy radiation (exposure) referred to in the embodiment is a concept including radiation of any energy ray capable of removing the liquid repellent materials on the opening part from the photocatalyst containing layer. Thus, the energy radiation is not limited to visible ray radiation.

The energy used in the embodiment is not particularly limited as long as the energy is capable of exciting the photocatalyst in the photocatalyst containing layer. Usually, the wavelength of light used in this energy radiation is set to 400 nm or less, preferably 380 nm or less. As described above, a preferred example of the photocatalyst used in the photocatalyst containing layer is titanium dioxide; the energy for activating the photocatalyst action by the titanium dioxide is preferably light of the above-mentioned wavelength.

Examples of a light source that can be used in the energy radiation include a mercury lamp, a metal halide lamp, a xenon lamp, an excimer lamp, and various other light sources.

Besides the method of radiating the energy by use of the above-mentioned light source, it is possible to use a method of using a laser such as an excimer laser or a YAG laser to draw the energy in a pattern form.

The radiation quantity of the energy in the energy radiation is set to a radiation quantity necessary for decomposing and removing the liquid repellent materials on the opening part partitioned by the light shielding part by such as the action of the photocatalyst in the photocatalyst containing layer.

At this time, it is preferable to radiate the energy while heating the photocatalyst containing layer since the sensitivity can be raised so that the liquid repellent materials can be effectively removed. Specifically, it is preferable to heat the layer within the range of 30 to 80° C.

### (2) Second Embodiment

Next, the second embodiment of the method for the energy radiating in the liquid repellent material removing step is described. As illustrated in, for example, FIG. 8, the second embodiment is an embodiment of preparing a photocatalyst processing layer side substrate 13 having a base body 11, and a photocatalyst processing layer 12 formed on the base body 11 and containing at least a photocatalyst, arranging the photocatalyst processing layer 12 and opening part 7 oppositely to each other, and radiating energy 8 to the entire surface from the side of the base material 1 to remove liquid repellent materials present on the surface of the opening part 7 partitioned by the light shielding part 6.

According to the embodiment, the energy is radiated in a state that the photocatalyst processing layer and the opening part are opposed to each other; therefore, the liquid repellent materials present on the opening part surface can be removed not only by the action of the photocatalyst in the photocatalyst containing layer formed at the side of the base material but also by the action of the photocatalyst in the photocatalyst processing layer, which accompanies the energy radiation. The light shielding part is formed on the base material and the energy radiation is performed from the base material side; therefore, even if the energy is radiated to the entire surface, the energy can be radiated only to the opening part partitioned by the light shielding part. Accordingly, the embodiment has an advantage that the liquid repellent material removing step can be effectively attained. Hereinafter, the photocatalyst processing layer side substrate used in the present step and the radiated energy will be described.

(Photocatalyst Processing Layer Side Substrate)

First, the photocatalyst processing layer side substrate used in the embodiment is described. This photocatalyst processing layer side substrate is not particularly limited as long as the substrate is a substrate having a base body and a photocatalyst processing layer formed on the base body.

The base body used in this photocatalyst processing layer side substrate is not particularly limited as long as the body is a body on which the photocatalyst processing layer can be formed. The base body may be, for example, a flexible resin film, or a non-flexible member such as a glass substrate.

An anchor layer may be formed on the base body in order to improve the adhesive property between the base body surface and the photocatalyst processing layer, or prevent the base body from being deteriorated by the action of the photocatalyst. An example of this anchor layer is a film made of a silane or titanium based coupling agent, or a silica film formed by such as reactive sputtering or CVD.

The photocatalyst processing layer of the photocatalyst processing layer side substrate used in the embodiment may be equivalent to the above-mentioned photocatalyst containing layer. Thus, detailed description will not be described herein.

(Energy Radiation)

Next, the energy radiation in the embodiment is described. In the embodiment, the opening part partitioned by the light shielding part and the photocatalyst processing layer of the photocatalyst processing layer side substrate are arranged so as to have a predetermined gap, and then energy is radiated thereto from the base material side. In this case, energy is shielded in the region where the light shielding part is formed; therefore, the energy can be radiated only to the opening part, which is a region where the light shielding part is not formed. Thus, the liquid repellent materials present in the opening part can be removed by the action of the photocatalyst containing layer and the photocatalyst processing layer, which accompanies the energy radiation.

The above-mentioned arrangement means a state that the opening part and the photocatalyst processing layer are arranged in such a manner that the action of the photocatalyst in the photocatalyst processing layer is substantially given to the opening part. Thus, the state is a state that the photocatalyst processing layer and the light shielding part adhere closely to each other, or a state that the photocatalyst processing layer and the opening part are arranged to have a predetermined gap. This gap is preferably a gap having an interval of 200 μm or less.

The gap in the embodiment has an interval preferably from 0.2 to 10 μm, more preferably from 1 to 5 μm since the sensitivity of the photocatalyst is high so that the efficiency of removing the liquid repellent materials on the opening part becomes good. Such an interval range of the gap is in particular effective for small-area opening part, which makes it possible to control the interval with a particularly high accuracy.

Meanwhile, when the opening part has a large area, for example, an area of 300 mm×300 mm or a larger area are processed, it is very difficult to make fine gaps as described above between the photocatalyst processing layer side substrate and the opening part. Accordingly, when the opening part has a relatively large area, the interval of the gap is preferably from 10 to 100 μm, more preferably from 50 to 75 μm. When the interval is set into such a range, there are not caused a problem that the precision of the pattern falls, a problem that the sensitivity of the photocatalyst deteriorates so that the efficiency of removing the liquid repellent materials deteriorates, or other problems. Furthermore, produced is an advantageous effect that the liquid repellent materials in the opening part are uniformly removed without unevenness.

When energy is radiated to the opening part having a relatively large area in this way, it is preferable to set the interval of a gap in a unit for positioning the photocatalyst processing layer side substrate and the opening part in an energy radiating device into the range preferably from 10 to 200 μm, more preferably from 25 to 75 μm. When the set value is within such a range, the arrangement can be attained without deteriorating the sensitivity of the photocatalyst to a large extent.

When the photocatalyst processing layer and the opening part surface are arranged to be separated at the given interval in this way, active oxygen species generated by oxygen, water and the photocatalyst action are easily desorbed. In other words, when the interval between the photocatalyst processing layer and the opening part of the base material is made narrower than the above-mentioned range, the active oxygen species are not easily desorbed so that the rate of removing the liquid repellent materials may be unfavorably made small. When they are arranged to have a larger interval than the above-mentioned range, the generated active oxygen species do not reach the opening part easily. In this case also, the rate of removing the liquid repellent materials may be unfavorably made small.

The method for arranging the photocatalyst processing layer and the opening part to make such a very narrow gap uniformly may be, for example, a method of using a spacer. When the space is used, a uniform gap can be made. Additionally, when the space is used, the active oxygen species generated by the action of the photocatalyst reach the base material surface at a high concentration without diffusing. Thus, the liquid repellent materials on the opening part can be effectively removed.

In the case of using the photocatalyst processing layer side substrate wherein the photocatalyst processing layer is formed on a flexible base body such as a flexible resin film, it is difficult to make a gap as described above. Thus, from the viewpoint of production efficiency and others, the photocatalyst processing layer and the light shielding part are preferably arranged so as to be contacted by each other.

In the embodiment, it is sufficient that such an arrangement state of the photocatalyst processing layer side substrate is kept at shortest only during the energy radiation.

The energy used in the embodiment is not particularly limited as long as the energy makes it possible to excite the photocatalyst in the photocatalyst containing layer and the photocatalyst processing layer, and may be the same as described in the first embodiment. The radiation quantity of the energy in the energy radiation is set to a radiation quantity necessary for decomposing the liquid repellent materials present in the opening part partitioned by the light shielding part by the action of the photocatalyst in the photocatalyst processing layer.

In the present embodiment also, the sensitivity of the photocatalyst can be made high by performing the energy radiation while heating the photocatalyst processing layer. Thus, the liquid repellent materials can be favorably removed with a high efficiency. Specifically, it is preferable that the layer is heated within the range of 30 to 80° C.

### (3) Third Embodiment

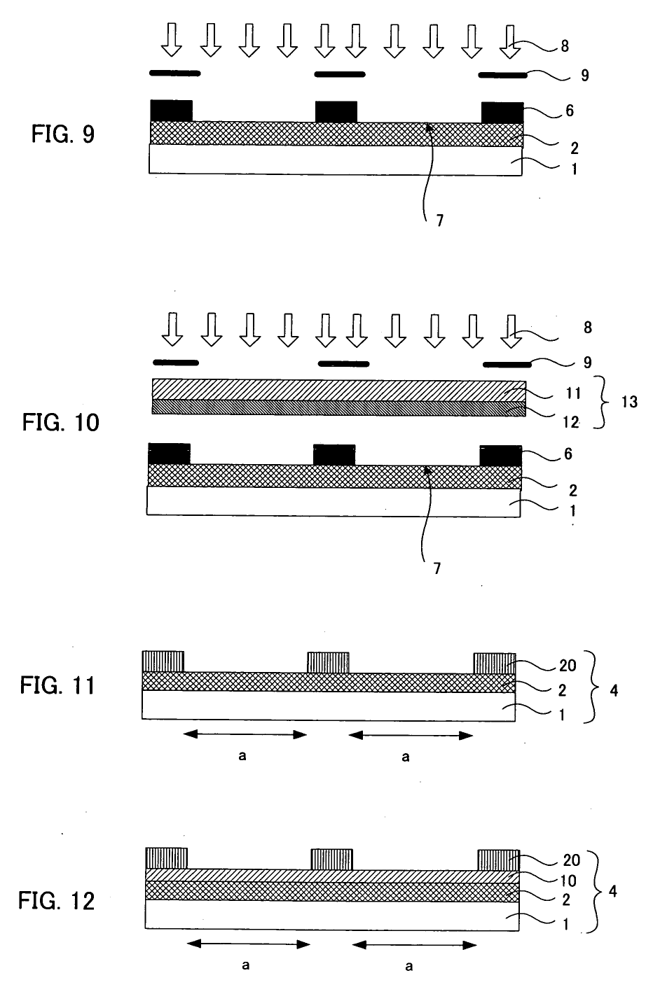

Next, the third embodiment of the method for the energy radiating in the liquid repellent material removing step is described. As illustrated in, for example, FIG. 9, the third embodiment of the method for the energy radiating in the present step is an embodiment of radiating energy 8 to the opening part 7 partitioned by the light shielding part 6 from the side of the light shielding part 6 of the base material 1, on which the light shielding part 6 is formed, using, for example, a photomask 9, thereby removing liquid repellent materials present on the surfaces of the opening part 7.

According to the embodiment, the energy is radiated to the opening part partitioned by the light shielding part from the side of the light shielding part, whereby the liquid repellent materials present on the opening part surface can be removed by the action of the photocatalyst accompanying the energy radiation. The embodiment has an advantage that the liquid repellent materials on the opening part surface can be removed even if the base material does not transmit the energy.

The energy radiated in the embodiment is not particularly limited as long as the energy makes it possible to excite the photocatalyst in the photocatalyst processing layer to remove the liquid repellent materials present on the surfaces of the opening part partitioned by the light shielding part. Thus, energy as described in the first embodiment can be used. In the embodiment, the energy can be radiated only to the opening part by energy radiation using, for example, a photomask, drawing radiation, or the like.

### (4) Fourth Embodiment

Next, the fourth embodiment of the method for the energy radiating in the liquid repellent material removing step is described. As illustrated in, for example, FIG. 10, the fourth embodiment of the method for the energy radiating in the step is an embodiment of preparing a photocatalyst processing layer side substrate 13 having a base body 11, and a photocatalyst processing layer 12 formed on the base body 11 and containing at least a photocatalyst, arranging the photocatalyst processing layer 12 and the light shielding part 6 oppositely to each other, and radiating energy 8 thereto from the side of the photocatalyst processing layer side substrate 13, using, for example, a photomask 9, thereby removing liquid repellent materials present on the surface of the opening part 7 partitioned by the light shielding part 6.

According to the embodiment, the liquid repellent materials on the opening part surface can be removed not only by the action of the photocatalyst in the photocatalyst containing layer formed at the side of the light shielding part but also by the action of the photocatalyst in the photocatalyst processing layer. Thus, the present step can be effectively performed. Moreover, the embodiment has an advantage that the liquid repellent materials on the opening part surface can be removed even if the base material does not transmit the energy.

The energy radiated in the embodiment is not particularly limited as long as the energy makes it possible to excite the photocatalyst in the photocatalyst containing layer and the photocatalyst processing layer to remove the liquid repellent materials present on the surfaces of the opening part partitioned by the light shielding part by the action of the photocatalyst. Thus, energy as described above in the first embodiment can be used. In the embodiment, the energy can be radiated only to the opening part by a method of radiating the energy into a pattern form by using a photomask or the like when the energy is radiated or by forming a photocatalyst processing layer side light shielding part in the photocatalyst processing layer side substrate, or a method of using a laser as described in the first embodiment to perform drawing radiation. The photocatalyst processing layer side light shielding part which can be formed in the photocatalyst processing layer side substrate can be formed by use of the same method and material for forming the above-mentioned light shielding part, formed on the base material. The photocatalyst processing layer side light shielding part may be formed on the photocatalyst processing layer, or between the base body and the photocatalyst processing layer. Furthermore, the light shielding part may be formed on the base body side opposite to the base body side on which the photocatalyst processing layer is formed.

The photocatalyst processing layer side substrate used in the embodiment, the method for arranging the photocatalyst processing layer side substrate, and others may be the same as in the second embodiment. Thus, detailed description thereof will not be described herein.

c. Others

The pattern formed body obtained in the aspect can be used for various purposes. The pattern formed body is preferably used to form a color filter wherein a colored layer is formed in the opening part. When the colored layer is formed by a jetting method such as an ink jet method, the color filter can be obtained with a high process efficiency. In this case, the used base material is a transparent base material which is transparent to visible rays. Specifically, the base material may be made of an inorganic material such as glass, or an organic material such as transparent resin.

For example, in the description about the method for manufacturing the pattern formed body, the case that the liquid repellent material removing step is performed after the plasma radiating step is performed has been described mainly. However, the aspect is not limited to this case. The aspect includes the case that the plasma radiating step is performed after the liquid repellent material removing step is performed. In this case, an impurity removing step may be performed before the plasma radiating step. In this case, energy in the impurity removing step may be radiated to the entire surface from the side of the light shielding part.

B. Pattern Formed Body

The following will describe the pattern formed body of the aspect. The pattern formed body is classified into the following two embodiments in accordance with the layer structure thereof or others. Each of the embodiments will be described hereinafter.

### (1) First Embodiment

First, the first embodiment of the pattern formed body of the aspect is described. The pattern formed body is a body having a base material, a photocatalyst containing layer formed on the base material and containing at least a photocatalyst, and a liquid repellent resin layer formed in a pattern form on the photocatalyst containing layer and containing, in its surface, a fluorine atom wherein a region of the photocatalyst containing layer where the liquid repellent resin layer is not formed is rendered a lyophilic region which contains, in its surface, no fluorine atom.

As illustrated in FIG. 11, an example of the pattern formed body of the present embodiment is an example wherein a photocatalyst containing layer 2 is formed on a base material 1 and further a liquid repellent resin layer 20 is formed thereon in a pattern form. In the embodiment, the surface of the liquid repellent resin layer 20 contains a fluorine atom, and the surface of region where the photocatalyst containing layer 2 is exposed (a region represented by “a” in FIG. 11) is rendered a lyophilic region containing no fluorine atom.

In the pattern formed body of the embodiment, a difference in wettability between the upper face of the liquid repellent resin layer and the region where the photocatalyst containing layer is exposed is used to make it possible to form a functional part with a high precision only in the region where the photocatalyst containing layer is exposed.

When the functional part made of a color layer or the like are formed in the opening part in the pattern formed body of the embodiment to manufacture a functional element such as a color filter, the photocatalyst containing layer contains, in its surface, no fluorine atom; thus, the pattern formed body has an advantage that it is possible to prevent the fluorine atom in the photocatalyst containing layer surface from eluting out in subsequent steps to give a bad effect onto the functional part.

In the embodiment, the photocatalyst containing layer surface contains no fluorine atom, so that a possibility that inconveniences as described above are generated is not produced. Thus, produced is an advantage that the quality of a functional element obtained by use of the pattern formed body of the embodiment can be made good.

About the pattern formed body of the embodiment, each of the constituents thereof will be described hereinafter.

(Photocatalyst Containing Layer)

The photocatalyst containing layer used in the embodiment is not particularly limited as long as the layer contains a photocatalyst and contains, in its surface, no fluorine atom inside the region where the liquid repellent resin layer that will be detailed later is not formed. The wording “contains, in its surface, no fluorine atom” in the embodiment means the following case: when the number of metal atoms of the photocatalyst contained in the photocatalyst containing layer surface in measurement by X-ray photoelectron spectroscopy (may referred to as ESCA (Electron Spectroscopy for Chemical Analysis)) is regarded as 100, the number of fluorine atoms is 10 or less, preferably 5 or less. The photocatalyst containing layer surface referred to in the embodiment means a region extending inwards by 5 nm or less from the outermost surface of the photocatalyst containing layer.

The method for causing the photocatalyst containing layer to contain, in its surface, no fluorine atom inside the region where the liquid repellent resin layer, which will be detailed later, is not formed may be a method for manufacturing a pattern formed body by a method equivalent to the first embodiment of the above-mentioned item “A. Method for manufacturing pattern formed body”. According to this method, the photocatalyst is excited by light generated when plasma is radiated, so that organic groups and the like that are present on the photocatalyst containing layer surface inside the region where the resin layer is not formed can be decomposed. This makes it possible that, for example, even if organic groups having fluorine, and the like are contained in the photocatalyst containing layer, the fluorine atom is removed through the plasma radiating step.

The photocatalyst containing layer used in the embodiment is preferably a photocatalyst containing layer the whole of which never contains any fluorine atom. According to this, when a functional part made of a colored layer or the like are formed in the lyophilic region, the fluorine atom can be further prevented from eluting out so as to give a bad effect onto the functional part.

In this case, the photocatalyst containing layer is usually rendered a layer made of an inorganic material. Specifically, the following cases correspond to the case that the photocatalyst containing layer is made of an inorganic material: a case where the photocatalyst containing layer is made of a photocatalyst, and a case where the photocatalyst containing layer is composed of a photocatalyst and a binder containing no fluorine atom.

In the embodiment, the film thickness of the photocatalyst containing layer is preferably in the range from 0.05 to 20 μm, whereby the light transmittance of the pattern formed body can be made good and further the haze value can be lowered. Thus, for example, when the pattern formed body is used as a display element such as a color filter, advantages are produced.

In the embodiment, the region of the photocatalyst containing layer where the liquid repellent resin layer, which will be detailed later, is not formed is rendered a lyophilic region. The lyophilic region is defined as a region having a lower contact angle with liquid than adjacent region by 1° or more. In the region where the photocatalyst containing layer is exposed in the embodiment, the contact angle with water is preferably 60° or less, more preferably 40° or less, even more preferably 20° or less. If the region where the photocatalyst containing layer is exposed has a high contact angle with liquid, at the time of forming a functional part on the pattern formed body of the embodiment, the region may repel a functional part forming coating solution for the formation of the functional part. Thus, it becomes difficult to form the functional part with a high precision. The contact angle with water is measured by the above-mentioned method.

Other points of the photocatalyst containing layer used in the embodiment are the same as described in the above-mentioned item “A. Method for manufacturing pattern formed body”. Thus, description thereof will not be described herein.

An example of the binder material containing no fluorine atom, which is used in the embodiment, is a polysiloxane which does not have any substituent having a fluorine atom, such as a fluoroalkyl group.

Other points are the same as described in the above-mentioned item “A. Method for manufacturing pattern formed body”. Thus, description thereof will not be described herein.

(Liquid Repellent Resin Layer)

Next, the liquid repellent resin layer in the embodiment is described. The liquid repellent resin layer is not particularly limited as long as the layer is formed in a pattern form on the photocatalyst containing layer and contains, in its surface, a fluorine atom.

This liquid repellent resin layer is appropriately selected in accordance with the usage of the pattern formed body, and is, for example, a layer having light shielding property. This liquid repellent resin layer having light shielding property has advantages that when the pattern formed body of the embodiment is used as, for example, a color filter, the resin layer can be used as a black matrix which is a light shielding part of the color filter.

Whether or not fluorine is contained in the liquid repellent resin layer surface depends on whether or not the fluorine atom is present only in the surface when the resin layer is measured by X-ray photoelectron spectroscopy. The matter that fluorine atoms are present only in the liquid repellent resin layer surface usually means that the fluorine atom is contained in a region extending inwards by 5 nm or less from the outermost surface of the liquid repellent resin layer. At this time, the ratio of the number of the fluorine atoms is preferably 10% or more of the number of atoms of all elements present in the liquid repellent resin layer surface.

The film thickness of the liquid repellent resin layer may be set into the range from about 0.01 μm to 1 mm, preferably from about 0.1 μm to 0.1 mm.

The contact angle of the liquid repellent resin layer surface with liquid is preferably 61° or more, more preferably 80° or more, even more preferably 100° or more. This makes the following possible: when the pattern formed body of the invention is used to form a functional element, a functional part forming coating solution for forming a functional part, does not adhere onto the liquid repellent resin layer, so that the functional part is highly precisely formed only in the region where the liquid repellent resin layer is not formed. The contact angle with liquid is measured by the above-mentioned method.

(Base Material)

The base material used in the embodiment may be the same as described in the above-mentioned item “A. Method for manufacturing pattern formed body”. Thus, description thereof will not be described herein.

(Usage)

The method for manufacturing pattern formed body of the embodiment is usually used as a functional element wherein the functional part is formed in the opening part or the like. Specifically, the pattern formed body can be used as a color filter wherein the functional part made of a colored layer is made in the opening part, or the like. As will be detailed later, the pattern formed body is used as an organic EL element wherein an organic EL layer is formed on the lyophilic region, a microlens wherein a lens is formed in the lyophilic region, a cell culturing substrate wherein the lyophilic region is used as a cell culturing region.

### (2) Second Embodiment

Next, the second embodiment of the pattern formed body of the aspect is described. The pattern formed body of the present embodiment is a pattern formed body having a base material, a photocatalyst containing layer formed on the base material and containing at least a photocatalyst, an intermediate layer formed on the photocatalyst containing layer and containing a silane coupling agent or a polymer of the silane coupling agent, and a liquid repellent resin layer formed in a pattern form on the intermediate layer and containing, in its surface, a fluorine atom, wherein a region of the intermediate layer where the liquid repellent resin layer is not formed is a lyophilic region.

As illustrated in, for example, FIG. 12, the pattern formed body of the embodiment is a pattern formed body having a base material 1, a photocatalyst containing layer 2 formed on the base material 1, an intermediate layer 10 formed on the photocatalyst containing layer 2, and a liquid repellent resin layer 20 formed in a pattern form on the intermediate layer 10, wherein the surface of the liquid repellent resin layer 20 contains a fluorine atom. The region where the intermediate layer 10 is exposed (a region represented by “a” in FIG. 12) is rendered a lyophilic region, and the contact angle thereof with water is preferably set to a predetermined value or less. The lyophilic region is defined as a region having a lower contact angle with liquid than its adjacent region by 1° or more.

In the pattern formed body of the embodiment, the wettability difference between the upper face of the liquid repellent resin layer and the region where the intermediate layer is exposed is used to make it possible to form the functional part with a high precision only in the region where the intermediate layer is exposed. Since the intermediate layer is formed in the embodiment, the embodiment has advantages of making good adhesive property between the photocatalyst containing layer and the liquid repellent resin layer, or between the photocatalyst containing layer and the functional part made in the opening part.

About the pattern formed body of this embodiment, each of the constituents thereof will be described hereinafter.

(Intermediate Layer)

Next, the intermediate layer used in the embodiments is described. The intermediate layer is a layer formed on the base material that will be detailed later and further contains a silane coupling agent or a polymer thereof. A region where the liquid repellent resin layer is not formed is rendered a region made lyophilic. The contact angle of the upper face thereof with water is preferably set to a predetermined value or less.

The contact angle of the lyophilic region with liquid, specifically, with water is preferably 60° or less, more preferably 40° or less, even more preferably 20° or less. When the contact angle of the region with liquid is high, at the time of forming the functional part onto the lyophilic region of the pattern formed body of the invention, the region may repel a functional part forming coating solution for forming the functional part. Thus, the functional part forming coating solution does not wet or spread sufficiently. As a result, it may become difficult to form the functional part.

The intermediate layer used in the embodiment may consist only of a silane coupling agent or a polymer thereof, or further comprise a binder, and the like. The silane coupling agent, the polymer thereof, or the binder contained in such an intermediate layer may be the same as described in the second embodiment of the item “A. Method for manufacturing pattern formed body”. The method for forming the lyophilic region may be a method of radiating the plasma to the region where the intermediate layer is exposed, as described in the above-mentioned item “A. Method for manufacturing pattern formed body”.

(Liquid Repellent Resin Layer)

Next, the liquid repellent resin layer in the embodiment is described. The liquid repellent resin layer is not particularly limited as long as the layer is formed in a pattern form on the intermediate layer and contains, in its surface, fluorine. This liquid repellent resin layer may be the same as described in the first embodiment. Thus, further description thereof will not be described herein.

(Photocatalyst Containing Layer)

The photocatalyst containing layer used in the embodiment is not particularly limited as long as the layer is formed on the base material that will be detailed below and contains a photocatalyst. Other points of the photocatalyst containing layer used in the embodiment are the same as described in the above-mentioned item “A. Method for manufacturing pattern formed body”. Thus, description thereof will not be described herein.

(Base Material)

The base material used in the embodiment is the same as described in the above-mentioned item “A. Method for manufacturing pattern formed body”. Thus, description thereof will not be described herein.

(Usage)

The pattern formed body of the embodiment is a pattern formed body used in an ordinary way as a functional element wherein a functional part is formed in an opening part or the like. Specifically, the pattern formed body can be used as a color filter wherein a colored layer for the functional part is formed in the opening part, or some other product. As will be detailed later, the pattern formed body is used such for as an organic EL element wherein an organic EL layer is formed in the lyophilic region, a microlens wherein a lens is formed in the lyophilic region, or a cell culturing substrate wherein the lyophilic region is used as a cell culturing region.

### (3) Other Embodiments

The pattern formed body of the invention includes the following embodiment: an embodiment having a base material, a photocatalyst containing layer formed on the base material and containing a at least photocatalyst, and a light shielding part formed on the photocatalyst containing layer and containing at least a light shielding material and a resin, wherein the photocatalyst containing layer contains no fluorine atom.

As illustrated in FIG. 7B, an example of the pattern formed body of the embodiment is an example wherein a photocatalyst containing layer 2 is formed on a base material 1 and further a light shielding part 6 is formed thereon in a pattern form.

When a functional part made of a colored layer or the like is formed in an opening part in the pattern formed body of the embodiment to manufacture a functional element such as a color filter, the pattern formed body has the following advantages since the photocatalyst containing layer contains a fluorine atom: the fluorine atom in the photocatalyst containing layer can be prevented from eluting out in subsequent steps so as to give a bad effect onto the functional part.

Specifically, when, for example, an organopolysiloxane having a fluoroalkyl group is used as the binder in the photocatalyst containing layer, a colored layer may be formed into a color filter in the opening part in the state that the fluorine atom remains in the photocatalyst containing layer. In accordance with subsequent steps, the fluorine atom in the photocatalyst containing layer may elute out so as to be present into the colored layer. When such a color filter is used as a liquid crystal display, there remains a possibility that the fluorine atom in the colored layer may elute out, as ionic impurities, into its liquid crystal layer. It is known that the presence of such ionic impurities in the liquid crystal layer produces a bad effect onto display of the liquid crystal display device, or the like.

In the embodiment, the photocatalyst containing layer contains no fluorine atom; therefore, inconveniences as described above are never caused. Thus, given is an advantage that the quality of a functional element obtained by use of the pattern formed body of the embodiment can be made good.

About this pattern formed body of the embodiment, each of the constituents thereof will be described hereinafter.

(Photocatalyst Containing Layer)

The photocatalyst containing layer used in the embodiment is not particularly limited as long as the layer is a layer containing a photocatalyst and further contains no fluorine atom. In the present embodiment, “contains no fluorine atom” means that the fluorine atoms are 10 or less or preferably 5 or less when they are checked by measuring with X-ray Photoelectron Spectroscopy (may referred to as ESCA (Electron Spectroscopy for Chemical Analysis)) and the contained metal atoms of the photocatalyst are made 100.

Accordingly, the following cases correspond to the case that the photocatalyst containing layer is made of an inorganic material: a case where the photocatalyst containing layer is made of a photocatalyst, a case where the photocatalyst containing layer is made of a photocatalyst and a binder containing no fluorine atom, and other cases.

In the embodiment, the film thickness of the photocatalyst containing layer is in the range preferably from 10 to 200 nm, more preferably from 10 to 120 nm, even more preferably from 15 to 100 nm, whereby the light transmittance of the pattern formed body can be made good and further the haze value can be lowered. Thus, for example, when the pattern formed body is used as a display element such as a color filter, advantages are produced.

Other points of the photocatalyst containing layer used in the embodiment are the same as described in the above-mentioned item “A. Method for manufacturing pattern formed body”. Thus, description thereof will not be described herein.

An example of the binder material containing no fluorine atom, which is used in the embodiment, is a polysiloxane which does not have any substituent having a fluorine atom, such as a fluoroalkyl group.

Other points are the same as described in the above-mentioned item “A. Method for manufacturing pattern formed body”. Thus, description thereof will not be described herein.

(Light Shielding Part)

Next, the light shielding part in the embodiment is described. The light shielding part is the same as described in the above-mentioned item “A. Method for manufacturing pattern formed body”. Particularly preferable is a light shielding part containing fluorine in its surface.

The matter that the light shielding part contains fluorine in its surface means that when the part is measured with an X-ray photoelectron spectrometer (XPS: ESCALAB 220i-XL), the fluorine atom is present only in its surface.

(Base Material)

The base material used in the embodiment may be the same as described in the above-mentioned item “A. Method for manufacturing pattern formed body”. Thus, description thereof will not be described herein.

(Usage)

The method for manufacturing pattern formed body of the embodiment is usually used as a functional element wherein the functional part is formed in the opening part or the like. Specifically, the pattern formed body can be preferably used as a color filter wherein the functional part made of a colored layer is made in the opening part, or the like.

C. Color Filter

Next, the color filter of the invention is described. The color filter of the invention is a product wherein a colored layer is formed on the lyophilic region of the above-mentioned pattern formed body. On the above-mentioned pattern formed body are formed the lyophilic region where the photocatalyst containing layer or the intermediate layer is exposed and the liquid repellent resin layer with a high liquid repellency; therefore, a wettability difference therebetween is used to make it possible to form a colored layer only in the lyophilic region with a high precision.

When the pattern formed body of the first embodiment out of the embodiments described in the above-mentioned item “B. Pattern formed body” is used to form a color filter, the lyophilic region surface does not contain fluorine. For this reason, this case has an advantage that the color filter can be rendered a high quality color filter wherein no fluorine atom elutes into its colored layer from its photocatalyst containing layer.

When the pattern formed body of the second embodiment out of the embodiments described in the above-mentioned item “B. Pattern formed body” is used to form a color filter, the above-mentioned intermediate layer is formed. For this reason, the color filter has an advantage that the adhesive property between its colored layer formed in the lyophilic region and its photocatalyst containing layer can be made good.

It is preferable that a layer having light shielding property is used as the liquid repellent resin layer of the pattern formed body of the invention. This makes it possible to manufacture a color filter with a high production efficiency without forming a black matrix. In terms of the material for each members of the color filter of the invention, the manufacturing method thereof, and the like may be the same as those in ordinary color filters. Thus, description thereof will not be described herein.

D. Organic EL Element

Next, the organic EL element of the invention is described. The organic EL element of the invention is a product wherein an organic EL layer is formed on the above-mentioned lyophilic region. On the above-mentioned pattern formed body are formed the lyophilic region where the photocatalyst containing layer or the intermediate layer is exposed and the liquid repellent resin layer with a high liquid repellency; therefore, a wettability difference therebetween is used to make it possible to form an organic EL layer only in the lyophilic region with a high precision.

The organic EL layer is a layer made of one or more organic layers which comprise at least one light emitting layer. In other words, the organic EL layer is a layer which comprises at least one light emitting layer, and has a layer structure having one or more organic layers. When the organic EL layer is formed through a wet process based on coating, it is usually difficult to laminate many layers because of the use of solvents; thus, in many cases, the organic layer is made of one or two organic layers. However, the organic layer can be made to have a larger number of layers by devising organic materials therefor, or combining the coating with vacuum evaporation.

In terms of the material for each members of the organic EL element of the invention, the manufacturing method thereof, and the like may be the same as those in ordinary organic EL elements. Thus, description thereof will not be described herein.

E. Microlens

Next, the microlens of the invention is described. The microlens of the invention is a product wherein a lens is formed on the above-mentioned lyophilic region. On the above-mentioned pattern formed body are formed the lyophilic region where the photocatalyst containing layer or the intermediate layer is exposed and the liquid repellent resin layer with a high liquid repellency; therefore, a wettability difference therebetween is used to make it possible to form a lens only in the lyophilic region with a high precision.

In terms of the material for each members of the microlens of the invention, the manufacturing method thereof, and the like may be the same as those in ordinary microlens. Thus, description thereof will not be described herein.

F. Cell Culturing Substrate

Next, the cell culturing substrate of the invention is described. The cell culturing substrate is a product wherein the upper face of the lyophilic region is used to culture a cell. According to the invention, no cell adheres onto the liquid repellent resin layer by the liquid repellency of the upper face of the liquid repellent resin layer. This makes it possible to culture cells only on the lyophilic region, so that the cells can be cultured into the form of a highly precise pattern.

In terms of other members used in the cell culturing substrate of the invention, the cells to be cultured, and the like may be the same as those in ordinary cell culturing substrates. Thus, description thereof will not be described herein.

The invention is not limited to the above-mentioned embodiments. The embodiments are merely illustrative, and any embodiment that has substantially the same structure as embodies the technical conception recited in the claims for the present invention and that produces the same effects and advantages as the above-mentioned embodiments produce is included in the technical scope of the invention.

### EXAMPLES

### Example 1

1. Formation of a Photocatalyst Containing Layer

A product, ST-K03, manufactured by ISHIHARA SANGYO KAISHA, LTD. was diluted 10 times with isopropanol, and the resultant was uniformly coated onto a 370 mm×470 mm×0.7 mm glass substrate (base material) with a spin coater to yield a substrate with a photocatalyst containing layer having a film thickness of 0.10 μm.

2. Formation of a Light Shielding Part

A black resist containing carbon black (V-259 BK resist), manufactured by Nippon Steel Chemical Co., Ltd., was coated onto the photocatalyst containing layer, and then the resultant was exposed to light, developed and post-baked to form a light shielding part having a film thickness of 1.0 μm, a width of 20 μm, and an opening part of 280 μm square. In this way, a patterning substrate was formed.

3. Atmospheric Fluorine Plasma Treatment

CF₄ and N₂ were caused to flow onto the patterning substrate at 12 L/min, and 20 L/min, respectively. This treatment was conducted twice at a transporting rate of 0.5 m/min. The power output was set to 190 V/4.8 A.

4. Energy Radiation

Through a photomask having a light shielding part having pattern lines of 10 μm in width and spaces 290 μm in width, energy from a high-pressure mercury lamp (illuminance: 30 mW/cm² at 365 nm) was radiated to the opening part from the side of the photocatalyst containing layer of the patterning substrate for 300 seconds, so as to decompose and remove liquid repellent materials, thereby making the opening part lyophilic. In this way, a pattern formed body was manufactured. In this case, with respect to the photocatalyst containing layer at the center of the opening part, the contact angle thereof with pure water was 90° before the energy radiation while the contact angle was 10° or less after the energy radiation. The contact angles with the liquid were each a value obtained by dropping out a pure water droplet of 20 μm in diameter onto an area 50 μm square the center of the opening part, and then measuring the contact angle thereof with a micro contact angle meter (Microscopic contact angle meter MCA-1, manufactured by Kyowa Interface Science Co., Ltd).

5. Formation of a Colored Layer

A piezoeletrically driving ink jet device was used to jet a red thermosetting ink (viscosity: 5 cP) to the opening part, which was made hydrophilic so as to have a varied wettability, and then the resultant was subjected to heating treatment to yield a red colored layer (thickness: 1.5 μm) on the patterning substrate. The colored layer wetted and spread onto wall faces of the light shielding part, and white spots were not generated.

The above-mentioned viscosity was a value measured with a viscometer, VIBROVISCOMETER CJV 5000 (manufactured by A & D Co. LTD.) at a temperature of 20° C.

Next, blue and green colored layers were formed in the same way. As a result, a color filter was manufactured wherein no white spots were generated in these layers in the same manner as in the red colored layer.

### Example 2

1. Formation of a Photocatalyst Containing Layer

A product, ST-K03, manufactured by ISHIHARA SANGYO KAISHA, LTD. was diluted 10 times with isopropanol, and the resultant was uniformly coated onto a 370 mm×470 mm×0.7 mm glass substrate (base material) with a spin coater to yield a substrate with a photocatalyst containing layer having a film thickness of 0.10 μm.

2. Formation of a Light Shielding Part

A black resist containing carbon black (V-259 BK resist), manufactured by Nippon Steel Chemical Co., Ltd., was coated onto the photocatalyst containing layer, and then the resultant was exposed to light, developed and post-baked to form a light shielding part having a film thickness of 1.0 μm, a width of 20 μm, and opening part of 280 μm square. In this way, a patterning substrate was formed.

3. Atmospheric Fluorine Plasma Treatment

CF₄ and N₂ were caused to flow onto the patterning substrate at 12 L/min, and 20 L/min, respectively. This treatment was conducted twice at a transporting rate of 0.5 m/min. The power output was set to 190 V/4.8 A.

4. Energy Radiation

Light from a high-pressure mercury lamp (illuminance: 30 mW/cm² at 365 nm) was radiated to the patterning substrate from the side of the base material thereof for 300 seconds to decompose and remove liquid repellent materials, thereby making the opening part lyophilic. In this way, a pattern formed body was manufactured. In this case, with respect to the photocatalyst containing layer at the center of the opening part, the contact angle thereof with pure water was 90° before the energy radiation while the contact angle was 10° or less after the energy radiation. The contact angles with the liquid were measured by the above-mentioned method.

5. Formation of a Colored Layer

A piezoelectrically driving ink jet device was used to jet a red thermosetting ink (viscosity: 5 cP) to the portion, which was made hydrophilic so as to have a varied wettability, and then the resultant was subjected to heating treatment to yield a red colored layer (thickness: 1.5 μm) on the patterning substrate. The colored layer wetted and spread onto wall faces of the light shielding part, and white spots were not generated.

The above-mentioned viscosity was a value measured with a viscometer, VIBROVISCOMETER CJV 5000 (manufactured by A & D Co. LTD.) at a temperature of 20° C.

Next, blue and green colored layers were formed in the same way. As a result, a color filter was manufactured wherein no white spots were generated in these layers in the same manner as in the red colored layer.

### Example 3

1. Formation of a Photocatalyst Processing Layer Side Substrate

A product, ST-K03, manufactured by ISHIHARA SANGYO KAISHA, LTD. was diluted 10 times with isopropanol, and the resultant was uniformly coated onto a 370 mm×470 mm×0.5 mm glass substrate (base body) with a spin coater to yield a photocatalyst processing layer side substrate with a photocatalyst processing layer formed and having a film thickness of 0.15 μm.

At this time, the following was used as the photocatalyst processing layer side substrate: a substrate wherein light shielding layer lines each having a width of 10 μm and opening part each having a width of 290 μm were formed into the form of stripes between the photocatalyst processing layer and the quartz substrate (base body).

2. Energy Radiation

The photocatalyst processing layer side substrate was opposed to a fluorine-plasma-treated patterning substrate yielded through the steps up to “3. Atmospheric fluorine plasma treatment” in the same way as in Example 1, so as to arrange the photocatalyst processing layer inwards and have an interval of 50 μm therebetween. A high-pressure mercury lamp (illuminance: 30 mW/cm² at 365 nm) was used to subject alignment exposure to the resultant from the side of the photocatalyst processing layer side substrate for 300 seconds. In this way, a pattern formed body was manufactured wherein the opening part and inner portion extending inwards by 5 μm from the end of the light shielding part were made lyophilic. In this case, with respect to the photocatalyst containing layer at the center of the opening part, the contact angle thereof with pure water was 90° before the energy radiation while the contact angle was 10° or less after the energy radiation. The contact angles with the liquid were obtained by the above-mentioned measuring method.

3. Formation of a Colored Layer

A piezoelectrically driving ink jet device was used to jet a red thermosetting ink (viscosity: 5 cP) to the portion, which was made hydrophilic so as to have a varied wettability, and then the resultant was subjected to heating treatment to yield a red colored layer (thickness: 1.5 μm) on the patterning substrate. The colored layer wetted and spread onto wall faces of the light shielding part, and white spots were not generated.

The above-mentioned viscosity was a value measured with a viscometer, VIBROVISCOMETER CJV 5000 (manufactured by A & D Co. LTD.) at a temperature of 20° C.

Next, blue and green colored layers were formed in the same way. As a result, a color filter was manufactured wherein no white spots were generated in these layers in the same manner as in the red colored layer.

### Example 4

1. Formation of a Photocatalyst Containing Layer Substrate

A product, ST-K03, manufactured by ISHIHARA SANGYO KAISHA, LTD. was diluted 10 times with isopropanol, and the resultant was uniformly coated onto a 370 mm×470 mm×0.5 mm glass substrate with a spin coater to yield a photocatalyst processing layer side substrate with a photocatalyst processing layer comprised and having a film thickness of 0.15 μm.

2. Energy Radiation

The photocatalyst processing layer side substrate was arranged onto a fluorine-plasma-treated patterning substrate yielded through the steps up to “3. Atmospheric fluorine plasma treatment” in the same way as in Example 1, so as to cause the photocatalyst processing layer and the light shielding part to adhere closely to each other. Thereafter, a high-pressure mercury lamp (illuminance: 30 mW/cm² at 365 nm) was used to expose the resultant to light from the side of the base material of the patterning substrate for 400 seconds. In this way, a pattern formed body was manufactured. In this case, with respect to the photocatalyst containing layer at the center of the opening part, the contact angle thereof with pure water was 90° before the energy radiation while the contact angle was 10° or less after the energy radiation. The contact angles with the liquid were measured by the above-mentioned measuring method.

3. Formation of a Colored Layer

A piezoelectrically driving ink jet device was used to jet a red thermosetting ink (viscosity: 5 cP) to the portion, which was made hydrophilic so as to have a varied wettability, and then the resultant was subjected to heating treatment to yield a red colored layer (thickness: 1.5 μm) on the patterning substrate. The colored layer wetted and spread onto wall faces of the light shielding part, and white spots were not generated.

The above-mentioned viscosity was a value measured with a viscometer, VIBROVISCOMETER CJV 5000 (manufactured by A & D Co. LTD.) at a temperature of 20° C.

Next, blue and green colored layers were formed in the same way. As a result, a color filter was manufactured wherein no white spots were generated in these layers in the same manner as in the red colored layer.

### Example 5

1. Formation of a Photocatalyst Processing Layer Side Substrate

A product, ST-K03, manufactured by ISHIHARA SANGYO KAISHA, LTD. was diluted 10 times with isopropanol, and the resultant was uniformly coated onto a 370 mm×470 mm×0.5 mm glass substrate with a spin coater to yield a photocatalyst processing layer side substrate comprising a photocatalyst processing layer and having a film thickness of 0.15 μm.

2. Energy Radiation

The photocatalyst processing layer side substrate was opposed to a fluorine-plasma-treated patterning substrate yielded through the steps up to “3. Atmospheric fluorine plasma treatment” in the same way as in Example 1, so as to arrange the photocatalyst processing layer inwards and have an interval of 50 μm therebetween. A high-pressure mercury lamp (illuminance: 30 mW/cm² at 365 nm) was used to subject an exposure to the resultant from the side of the base material side of the patterning substrate for 300 seconds. In this case, with respect to the photocatalyst containing layer at the center of the opening part, the contact angle thereof with pure water was 90° before the energy radiation while the contact angle was 10° or less after the energy radiation. The contact angles with the liquid were obtained by the above-mentioned measuring method.

3. Formation of a Colored Layer

A piezoelectrically driving ink jet device was used to jet a red thermosetting ink (viscosity: 5 cP) to the portion, which was made hydrophilic so as to have a varied wettability, and then the resultant was subjected to heating treatment to yield a red colored layer (thickness: 1.5 μm) on the patterning substrate. The colored layer wetted and spread onto wall faces of the light shielding part, and white spots were not generated.

The above-mentioned viscosity was a value measured with a viscometer, VIBROVISCOMETER CJV 5000 (manufactured by A & D Co. LTD.) at a temperature of 20° C.

Next, blue and green colored layers were formed in the same way. As a result, a color filter was manufactured wherein no white spots were generated in these layers in the same manner as in the red colored layer.

### Example 6

1. Formation of a Photocatalyst Containing Layer

A product, ST-K03, manufactured by ISHIHARA SANGYO KAISHA, LTD. was diluted 10 times with isopropanol, and the resultant was uniformly coated onto a 370 mm×470 mm×0.7 mm glass substrate with a spin coater to yield a substrate with a photocatalyst containing layer having a film thickness of 0.15 μm.

2. Formation of an Intermediate Layer

Mixed and stirred for 5 hours were 1.5 g of decyltrimethoxysilane, 5 g of tetramethoxysilane, and 2 g of 0.1 N hydrochloric acid. The resultant was diluted 10 times with isopropanol, and then the solution was uniformly coated onto the above-mentioned substrate with a photocatalyst containing layer by a spin coater to yield an intermediate layer having 0.1 μm film thickness.

3. Formation of a Resin Layer

A black resist containing carbon black (V-259 BK resist, manufactured by Nippon Steel Chemical Co., Ltd.) was coated onto the glass substrate wherein the intermediate layer was formed, and the resultant was exposed to light, developed and subjected to post-baking treatment to form a light shielding resin layer having a film thickness of 1.0 μm, a width of 20 μm, and an opening part of 280 μm squares.

4. Atmospheric Fluorine Plasma Treatment

CF₄ and N₂ were caused to flow onto the substrate at 12 L/min, and 20 L/min, respectively. This treatment was conducted twice at a transporting rate of 0.5 m/min. The power output was set to 190 V/4.8 A. Thereafter, the contact angle thereof to water was measured. As a result, the contact angle of the resin layer was 104°, and that of the opening part (the intermediate layer) was 6°.

5. Formation of a Colored Layer

A piezoelectrically driving ink jet device was used to jet a red thermosetting ink (viscosity: 5 cP) to the opening part, which was made hydrophilic. The resultant was then subjected to heating treatment to form a red colored layer (thickness: 1.5 μm) on the glass substrate having the resin layer. The colored layer wetted and spread onto wall faces of the resin layer, and white spots were not generated.

The above-mentioned viscosity was a value measured with a viscometer, VIBROVISCOMETER CJV 5000 (manufactured by A & D Co. LTD.) at a temperature of 20° C. Next, blue and green colored layers were formed in the same way and a color filter was manufactured wherein no white spots were generated in these layers in the same manner as in the red colored layer.

What is claimed is:

1. A method for manufacturing a pattern formed body comprising a plasma radiating step of radiating plasma to a patterning substrate having:
a base material;
a photocatalyst containing layer formed on the base material and containing at least a photocatalyst; and
a resin layer formed in a pattern form on the photocatalyst containing layer and containing at least a resin,
wherein a fluorine compound is used as an introduction gas to radiate the plasma to make an upper face of the resin layer liquid repellent.

2. The method for manufacturing a pattern formed body according to claim 1, wherein an intermediate layer containing a silane coupling agent or a polymer of the silane coupling agent is formed on the photocatalyst containing layer, and the resin layer is formed in the pattern form on the intermediate layer.

3. The method for manufacturing a pattern formed body according to claim 1 comprising a liquid repellent material removing step, wherein energy is radiated to an opening part partitioned by the resin layer to remove a liquid repellent material on a surface of the opening part.

4. The method for manufacturing a pattern formed body according to claim 1, wherein the resin layer is a light shielding part containing at least a light shielding material.

5. A pattern formed body comprising:
a base material;
a photocatalyst containing layer formed on the base material and containing at least a photocatalyst; and
a liquid repellent resin layer formed in a pattern form on the photocatalyst containing layer and containing a fluorine atom in its surface,
wherein a region of the photocatalyst containing layer where the liquid repellent resin layer is not formed is rendered a lyophilic region which does not contain fluorine in its surface.

6. A pattern formed body comprising:
a base material;
a photocatalyst containing layer formed on the base material and containing at least a photocatalyst;
an intermediate layer formed on the photocatalyst containing layer and containing a silane coupling agent or a polymer of the silane coupling agent; and
a liquid repellent resin layer formed in a pattern form on the intermediate layer and containing a fluorine atom in its surface,
wherein a region of the intermediate layer where the liquid repellent resin layer is not formed is a lyophilic region.

7. The pattern formed body according to claim 6, wherein the region of the intermediate layer where the liquid repellent resin layer is not formed is rendered the lyophilic region having a contact angle with water in its surface of 60° or less.

8. The pattern formed body according to claim 5, wherein the liquid repellent resin layer is a liquid repellent light shielding part containing at least a light shielding material.

9. The pattern formed body according to claim 6, wherein the liquid repellent resin layer is a liquid repellent light shielding part containing at least a light shielding material.

10. A color filter, wherein a colored layer is formed on the lyophilic region of the pattern formed body according to claim 5.

11. A color filter, wherein a colored layer is formed on the lyophilic region of the pattern formed body according to claim 6.

12. An organic electroluminescent element, wherein an organic electroluminescent layer is formed on the lyophilic region of the pattern formed body according to claim 5.

13. An organic electroluminescent element, wherein an organic electroluminescent layer is formed on the lyophilic region of the pattern formed body according to claim 6.

14. A microlens, wherein a lens is formed on the lyophilic region of the pattern formed body according to claim 5.

15. A microlens, wherein a lens is formed on the lyophilic region of the pattern formed body according to claim 6.

16. A cell culturing substrate, wherein an upper face of the lyophilic region of the pattern formed body according to claim 5 is used to culture a cell.

17. A cell culturing substrate, wherein an upper face of the lyophilic region of the pattern formed body according to claim 6 is used to culture a cell.
